(19) United States
(12) Patent Application Publication
(10) Pub. No.: US 2024/0224604 A1
(43) Pub. Date: Jul. 4, 2024

(54) DISPLAY PANEL AND METHOD FOR MANUFACTURING THE SAME

(71) Applicant: Samsung Display Co., Ltd., Yongin-si (KR)

(72) Inventors: HYUNEOK SHIN, Yongin-si (KR); SUNGJOO KWON, Yongin-si (KR); JOONYONG PARK, Yongin-si (KR)

(73) Assignee: Samsung Display Co., Ltd., Yongin-si (KR)

(21) Appl. No.: 18/401,911

(22) Filed: Jan. 2, 2024

(30) Foreign Application Priority Data
Jan. 4, 2023 (KR) 10-2023-0001251

(51) Int. Cl. H10K 59/122; H10K 59/12

(52) U.S. Cl. CPC H10K 59/122; H10K 59/1201

(57) ABSTRACT

A display panel includes a base layer, a lower pixel defining layer having first and second light emitting openings which are defined in the lower pixel defining layer, an upper pixel defining layer having first and second upper openings which are defined in the upper pixel defining layer, and overlapping the first and second light emitting openings, respectively, a first light emitting element including a first electrode, a first protective layer, a first light emitting pattern, and a second electrode and disposed in the first upper opening, and a second light emitting element including a first electrode, a second protective layer, a second light emitting pattern, and a second electrode and disposed in the second upper opening. Each of the first protective layer and the second protective layer is a display panel including a titanium oxide.

### CROSS-REFERENCE TO RELATED APPLICATION(S)

This application claims priority to and benefits of Korean Patent Application No. 10-2023-0001251 under 35 U.S.C. § 119, filed on Jan. 4, 2023 in the Korean Intellectual Property Office, the entire contents of which are incorporated herein by reference.

### BACKGROUND

### 1. Technical Field

Embodiments of the disclosure described herein relate to an organic light emitting display panel and a method for manufacturing the same.

### 2. Description of the Related Art

Multimedia electronic devices, such as televisions, mobile phones, tablets, navigation, or game consoles, may include a display panel to display an image. An organic light emitting display panel may feature lower power consumption, a higher brightness, and a higher reaction rate.

The display panel may include a light emitting element and a pixel circuit to drive the light emitting element, and the light emitting element may include an anode, a cathode, and a light emitting pattern. The light emitting pattern may be formed separately for each of multiple light emitting regions, and the cathode may provide a common voltage to the light emitting elements disposed in the light emitting regions.

### SUMMARY

Embodiments of the disclosure provide a display panel including a light emitting element formed without using a metal mask, and improved in reliability, and a method for manufacturing the same.

According to an embodiment, a display panel may include a base layer, a lower pixel defining layer disposed on the base layer and having a first light emitting opening and a second light emitting opening which are defined in the lower pixel defining layer, an upper pixel defining layer disposed on the lower pixel defining layer and having a first upper opening and a second upper opening which are defined in the upper pixel defining layer, and which overlap the first light emitting opening and the second light emitting opening, respectively, a first light emitting element including a first electrode, a first protective layer, a first light emitting pattern, and a second electrode and disposed in the first upper opening, and a second light emitting element including a first electrode, a second protective layer, a second light emitting pattern, and a second electrode and disposed in the second upper opening. Each of the first protective layer and the second protective layer may include a titanium oxide.

The first protective layer may overlap the first light emitting opening, and the second protective layer may overlap the second light emitting opening.

The first protective layer may contact the first electrode of the first light emitting element, and the second protective layer may contact the first electrode of the second light emitting element.

Each of the first protective layer and the second protective layer may have a thickness in a range of about 30 Å to about 50 Å.

The first protective layer may overlap an inner side surface of the lower pixel defining layer defining the first light emitting opening, and the second protective layer may overlap an inner side surface of the lower pixel defining layer defining the second light emitting opening.

Each of the first electrode of the first light emitting element and the first electrode of the second light emitting element may include first to fourth conductive layers, and at least two conductive layers of the first to fourth conductive layers may include mutually different materials.

The first conductive layer and the fourth conductive layer may include a same material.

The second conductive layer may include silver (Ag), magnesium (Mg), aluminum (Al), platinum (Pt), palladium (Pd), gold (Au), nickel (Ni), neodymium (Nd), iridium (Ir), chromium (Cr), or a combination thereof.

The third conductive layer may include at least one of indium gallium zinc oxide (IGZO), indium zinc oxide (IZO), and indium zinc tin oxide (IZTO).

The fourth conductive layer may include indium tin oxide (ITO).

The third conductive layer may have a thickness less than a thickness of the fourth conductive layer.

The third conductive layer may have a thickness in a range of about 200 Å to about 300 Å

The fourth conductive layer may have a thickness in a range of about 50 Å to about 100 Å.

The upper pixel defining layer may surround the second electrode of the first light emitting element and the second electrode of the second light emitting element, when viewed in a plan view.

The upper pixel defining layer may include a first upper layer disposed on the lower pixel defining layer and including a conductive material, and a second upper layer disposed on the first upper layer, and each of the second electrode of the first light emitting element and the second electrode of the second light emitting element may contact inner surfaces of the first upper layer.

The second upper layer may include a conductive material different from a material of the first upper layer.

The first upper layer may include an inner side surface defining the first upper opening, the second upper layer may include an inner side surface overlapping the first upper opening, and the inner surface of the second upper layer may protrude more than the inner side surface of the first upper layer toward center of the first upper opening.

The first light emitting element and the second light emitting element may emit mutually different color lights.

According to an embodiment, a display panel may include a base layer including a light emitting region and a non-light emitting region, a lower pixel defining layer disposed in the non-light emitting region and including an insulating material, an upper pixel defining layer disposed on the lower pixel defining layer and including a conductive material, and a light emitting element disposed in the light emitting region. The light emitting element may include a first electrode disposed on the base layer, a protective layer disposed on the first electrode and including a titanium oxide, a light emitting pattern disposed on the protective layer, and a second electrode disposed on the light emitting pattern. The protective layer may overlap a top surface of the first electrode corresponding to the light emitting region.

According to an embodiment, a method for manufacturing a display panel, the method may include providing a preliminary display panel including a base layer, a first electrode disposed on the base layer, a preliminary lower pixel defining layer overlapping the first electrode, and a preliminary upper pixel defining layer overlapping the preliminary lower pixel defining layer, forming an upper pixel defining layer having an upper opening defined in the upper pixel defining layer by patterning the preliminary upper pixel defining layer, forming a lower pixel defining layer having a light emitting opening overlapping the upper opening by patterning the preliminary lower pixel defining layer, forming a protective layer including titanium oxide on the first electrode exposed through the light emitting opening, forming a light emitting pattern on the protective layer, and forming a second electrode contacting the upper pixel defining layer, in the upper opening.

### BRIEF DESCRIPTION OF THE DRAWINGS

The above and other aspects and features of the disclosure will become apparent by describing in detail embodiments thereof with reference to the accompanying drawings.

FIG. 1 is a schematic perspective view of a display device according to an embodiment of the disclosure.

FIG. 2 is an exploded schematic perspective view of a display device according to an embodiment of the disclosure.

FIG. 3 is a schematic cross-sectional view of a display module according to an embodiment of the disclosure.

FIG. 4 is a schematic plan view of a display panel according to an embodiment of the disclosure.

FIG. 5 is an expanded schematic plan view of a display region according to an embodiment of the disclosure.

FIG. 6 is a schematic cross-sectional view illustrating a display panel according to an embodiment of the disclosure.

FIG. 7A is a schematic cross-sectional view illustrating a display panel according to an embodiment of the disclosure.

FIG. 7B is a cross-sectional view illustrating a display panel according to a comparative example of the disclosure.

FIGS. 8A and 8B are schematic voltage-current graphs based on the configuration of a first electrode according to an embodiment.

FIG. 9 is a schematic flowchart illustrating a method for manufacturing a display panel according to an embodiment of the disclosure.

FIGS. 10A to 10H are schematic cross-sectional views illustrating operations in a method for manufacturing a display panel according to an embodiment of the disclosure.

FIGS. 11A to 11E are schematic cross-sectional views illustrating operations in a method for manufacturing a display panel according to a comparative example of the disclosure.

### DETAILED DESCRIPTION OF THE EMBODIMENTS

While the disclosure is susceptible to various modifications and alternative forms, specific embodiments thereof are shown by way of examples in the drawings and will herein be described in detail. It should be understood, however, that there is no intent to limit the disclosure to the particular forms disclosed, but on the contrary, the disclosure is to cover all modifications, equivalents, and alternatives falling within the spirit and scope of the disclosure.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

In the specification, the expression that a first component (or region, layer, part, portion, etc.) is “on”, “connected to”, or “coupled to” a second component means that the first component is directly on, connected to, or coupled to the second component or means that a third component is interposed therebetween.

It will be understood that the terms “connected to” or “coupled to” may include a physical and/or electrical connection or coupling.

The same reference numeral refers to the same component. In addition, in drawings, thicknesses, proportions, and dimensions of components may be exaggerated to describe the technical features effectively.

Although the terms “first”, “second”, etc. may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component.

In addition, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.”

About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in an ideal or overly formal meaning unless explicitly defined herein.

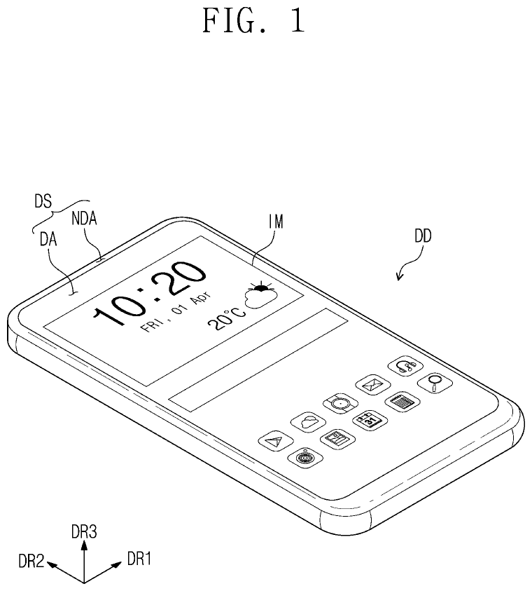

FIG. 1 is a schematic perspective view of a display device DD according to an embodiment of the disclosure.

Referring to FIG. 1, the display device DD may be a device activated in response to an electrical signal to display an image. According to an embodiment, the display device DD may be a small or medium-sized electronic device, such as a monitor, a cellular phone, a tablet PC, a navigator, a game console, or the like, or even a large-sized electronic device, such as a television, or an external billboard. However, embodiments of the display device DD are provided only for the illustrative purpose, and the display device DD is not limited to any particular embodiment. According to an embodiment, the display device DD is shown in the form of a cellular phone, by way of example.

The display device DD may be rigid or flexible. The “flexible” characteristic refers to a bendable characteristic, and the flexible structure may include all structures ranging from a fully folded structure to a structure bent by a level of several nanometers. For example, the flexible display device DD may include a curved device, a rollable device, and/or a foldable device.

The display device DD may have a shape of a rectangle having a shorter side extending in a first direction DR1 and a longer side extending in a second direction DR2 crossing the first direction DR1. However, embodiments are not limited thereto, and the display device DD may have various shapes, such as a circle shape or a polygon shape, when viewed in a plan view.

According to an embodiment, a third direction DR3 may be defined as a direction perpendicular to a plane defined by the first direction DR1 and the second direction DR2. The front surface (or top surface) and the rear surface (bottom surface) of each of members constituting the display device DD may be opposite to each other in the third direction DR3, and a normal direction to the front surface and the rear surface may parallel to the third direction DR3. The distance between the front surface and the rear surface defined in the third direction DR3 may correspond to the thickness of the member.

In the specification, the wording “in a plan view” may refer to the state when viewed in the third direction DR3. In the specification, the wording “in a cross-sectional view” may refer to the state when viewed in the first direction DR1 or the second direction DR2. The first direction DR1, the second direction DR2, and the third direction DR3 may be relative concepts and may be changed to different directions.

The display device DD may display an image through a display surface DS. The display surface DS may correspond to a front surface of the display device DD. The display surface DS of the display device DD may include a plane defined by the first direction DR1 and the second direction DR2, and an image may be displayed in the third direction DR3 crossing the first direction DR1 and the second direction DR2. The disclosure is not limited thereto. For example, the display surface DS may further include a curved surface bent from at least one side of the plane.

The display surface DS of the display device DD may have a display part DA and a non-display part NDA. The display part DA may be a region provided in the display surface DS to display an image IM. The image IM may be displayed in the third direction DR3 through the display part DA. The image IM may include a still image in addition to a moving picture image. FIG. 1 illustrates icons and clocks as one example of the image IM.

The non-display part NDA may be a region adjacent to the display part DA, and a region in which the image IM may not be displayed in the display surface DS. The non-display part NDA may be a region showing a lower light transmittance as compared to that of the display part DA. According to an embodiment, the non-display part NDA may surround the display part DA. However, the disclosure is not limited thereto. For example, the non-display part NDA may be provided at only one side of the display part DA or may be omitted.

The display device DD according to an embodiment may sense an external input applied from the outside. The external input may include various types of inputs. For example, the external input may include force, pressure, a temperature, or light. The external input may include an input (for example, hovering) applied in the vicinity of the display device DD, in addition to an input (for example, contact by a user hand or a pen) in contact with the display device DD.

According to an embodiment, the display device DD may further include various electronic modules. For example, the electronic module may include at least one of a camera, a speaker, a light sensing sensor, and a heat sensing sensor. The electronic module may sense an external subject received through the display surface DS or may provide a sound signal, such as a voice, to the outside through the display surface DS. The configuration of the electronic module of the display device DD is not limited to any one particular embodiment.

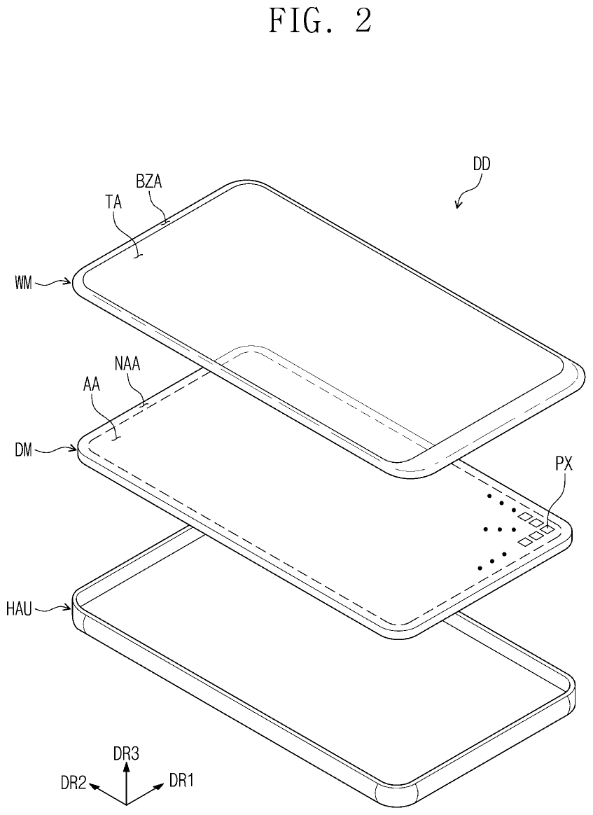

FIG. 2 is an exploded schematic perspective view of the display device DD according to an embodiment of the disclosure.

Referring to FIG. 2, the display device DD may include a window WM, a display module DM, and a housing HAU. However, the configuration of the display device DD is not limited to the illustrated embodiment, and may further include a functional layer, such as an anti-reflection layer, between the display module DM and the window WM, or an electronic module, such as a camera module and a battery module, between the display module DM and the housing HAU.

The window WM may be disposed on the display module DM. The window WM may cover the front surface of the display module DM and may protect the display module DM from an external impact and/or a scratch. The window WM may be connected to the display module DM through an adhesive layer.

The window WM may include an optically transparent material. For example, the window WM may include a glass film or a synthetic resin film, as a base film. The window WM may further include a functional layer such as an anti-fingerprint layer, a phase control layer, and/or a hard coating layer, disposed on the base film.

The front surface of the window WM may correspond to the front surface of the display device DD. The front surface of the window WM may include a transmission region TA and a bezel region BZA.

The transmission region TA may be an optically transparent region. The transmission region TA may transmit an image provided by the display module DM, and the user may visually recognize the image through the transmission region TA. According to an embodiment, although the transmission region TA is illustrated in a square form, the transmission region TA may have various forms, and is not limited to any one particular embodiment.

The bezel region BZA may be adjacent to the transmission region TA. The shape of the transmission region TA may be substantially defined by the bezel region BZA. For example, the bezel region BZA may be disposed outside the transmission region TA to surround the transmission region TA. However, this is illustrated as an example, and the bezel region BZA may be adjacent to only a side of the transmission region TA or may be disposed on a side surface of the display device DD rather than a front surface thereof.

The bezel region BZA may be a region having a light transmittance lower than a light transmittance of the transmission region TA. The bezel region BZA may correspond to a region printed with a material having a specific color. The bezel region BZA may prevent light from being transmitted, thereby preventing one component of the display module DM disposed to overlap the bezel region BZA from being visually recognized from the outside.

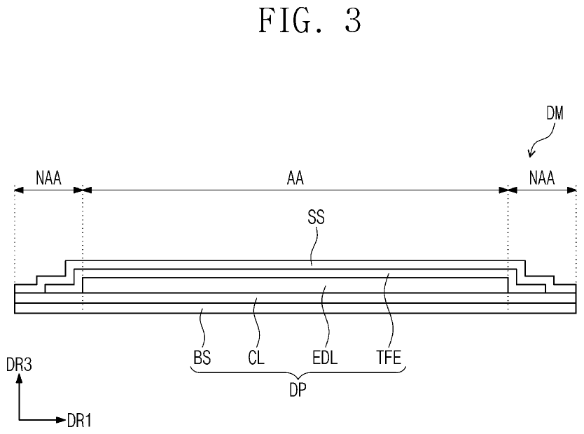

The display module DM may be interposed between the window WM and the housing HAU. The display module DM may include a display region AA and a non-display region NAA, which may correspond to the display region AA and the non-display region NAA of a display panel DP (see FIG. 3) to be described later. Pixels PX may be disposed in the display region AA to generate light corresponding to an electrical signal. The pixels PX may include a light emitting element, and may implement the image IM (see FIG. 1) based on light generated from the light emitting element. The display region AA may overlap at least a portion of the transmission region TA.

The non-display region NAA may be adjacent to the display region AA. For example, the non-display region NAA may surround the display region AA. However, the disclosure is not limited thereto, and the non-display region NAA may be defined in various shapes. The non-display region NAA may be a region in which a driving circuit, a signal line, a pad, and the like for driving a light emitting element are disposed in the display region AA. The non-display region NAA may overlap at least a part of the bezel region BZA, and components disposed in the non-display region NAA may be prevented from being visually viewed from the outside by the bezel region BZA.

The window WM and the housing HAU may be connected to each other to form an outer appearance of the display device DD. The display module DM may be received in an inner space formed by combining the window WM and the housing HAU.

The housing HAU may include a material having relatively high rigidity. For example, the housing HAU may include glass, plastic, or metal, or may include multiple frames and/or plates including combinations thereof. The housing HAU may protect the display module DM received in the housing HAU by absorbing impact applied from the outside or preventing foreign materials/water from being infiltrated into the display module DM from the outside.

FIG. 3 is a schematic cross-sectional view illustrating the display module DM according to an embodiment of the disclosure.

Referring to FIG. 3, the display module DM may include the display panel DP and an input sensor layer SS.

The display panel DP may display an image in response to an electrical signal. The display panel DP according to an embodiment may be an emissive-type display panel, but is not particularly limited thereto. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. The light emitting layer of the quantum dot light emitting display panel may include a quantum dot, a quantum rod, and/or the like. Hereinafter, the display panel DP is discussed as an organic light emitting display panel as an example.

The display panel DP may include a base layer BS, a circuit layer CL, a display element layer EDL, and an encapsulation layer TFE. The display panel DP may include the display region AA for displaying an image and the non-display region NAA surrounding the display region AA.

The base layer BS may provide a base surface for disposing the circuit layer CL. The base layer BS may be a rigid substrate, or a flexible substrate allowing bending, folding, and/or rolling. The base layer BS may be a glass substrate, a metal substrate, and/or a polymer substrate. However, embodiments are not limited thereto, and the base layer BS may be an inorganic layer, a synthetic resin layer, and/or a composite material layer.

The base layer BS may have a multi-layer structure. For example, the base layer BS may include synthetic resin layers and a multi-layered or single-layered inorganic layer interposed between the synthetic resin layers. Each of the synthetic resin layers may include an acrylic resin, a methacrylic resin, polyisoprene, a vinyl resin, an epoxy resin, a urethane resin, a cellulose resin, a siloxane resin, a polyamide resin, a perylene resin, and/or the like, but the material of the synthetic resin layers is not limited thereto.

The circuit layer CL may be disposed on the base layer BS. The circuit layer CL may include at least one of an insulating layer, a semiconductor pattern, and a conductive pattern. The insulating layer, the semiconductor pattern, and the conductive pattern included in the circuit layer CL may form driving elements, such as transistors, signal lines, and pads, in the circuit layer CL.

The display element layer EDL may be disposed on the circuit layer CL. The display element layer EDL may include light emitting elements disposed in the display region AA. For example, the light emitting elements may include an organic light emitting element, an inorganic light emitting element, an organic-inorganic light emitting element, a micro-LED, a nano-LED, a quantum dot light emitting element, an electrophoretic element, and/or an electrowetting element. The light emitting elements of the display element layer EDL may be electrically connected to the driving elements of the circuit layer CL to generate light in the display region AA according to a signal provided by the driving elements.

The encapsulation layer TFE may be disposed on the display element layer EDL to seal the light emitting elements. The encapsulation layer TFE may improve the optical efficiency of the display element layer EDL, or may include at least one thin film to protect the display element layer EDL. The encapsulation layer TFE may include at least one of an inorganic layer and an organic layer.

The input sensor layer SS may be disposed on the display panel DP. The input sensor layer SS may be disposed on the display panel DP through sequential processes. The input sensor layer SS may be directly disposed without a separate adhesive layer on the display panel DP. However, the disclosure is not limited thereto, but the input sensor layer SS may be connected to the display panel DP through the adhesive layer.

The input sensor layer SS may include at least one of an input sensor, an antenna sensor, and a fingerprint sensor. For example, the input sensor layer SS may include an input sensor, and the input sensor may sense an external input and provide an input signal including information on an external input, such that the display panel DP generates an image corresponding to the external input. The input sensor may be driven in various ways such as a capacitive scheme, a resistive scheme, an infrared scheme, a sound wave scheme, and/or a pressure scheme, but is not limited to any one of the schemes.

The display module DM is not limited to components illustrated in the drawing, but the display module DM may further include a protective member disposed under the display panel DP or an anti-reflective layer disposed on the display panel DP.

According to an embodiment, a protective member may be disposed on a rear surface of the display panel DP to protect the display panel DP from an external impact. The protective member may include a functional layer such as a cushion layer to absorb an impact, a heat radiation layer to prevent heat from being transferred to the display panel DP, and/or a shielding layer to block the reflection of light or electromagnetic waves.

According to an embodiment, an anti-reflection layer may be disposed on the input sensor layer SS. The anti-reflection layer may be disposed on the input sensor layer SS through a sequential process without an adhesive layer. The disclosure is not limited thereto. For example, the anti-reflection layer may be connected to the input sensor layer SS through the adhesive layer. The stack position of the anti-reflection layer may be interposed between the display panel DP and the input sensor layer SS.

The anti-reflection layer may include various embodiments to reduce the reflectance of the external light incident thereto from the outside of the display device DD (see FIG. 1). For example, the anti-reflection layer may include a polarizing film including a retarder and/or a polarizer, multilayer reflecting layers that offset or interfere reflected light, or color filters arranged corresponding to the arrangement of pixels PX (see FIG. 2).

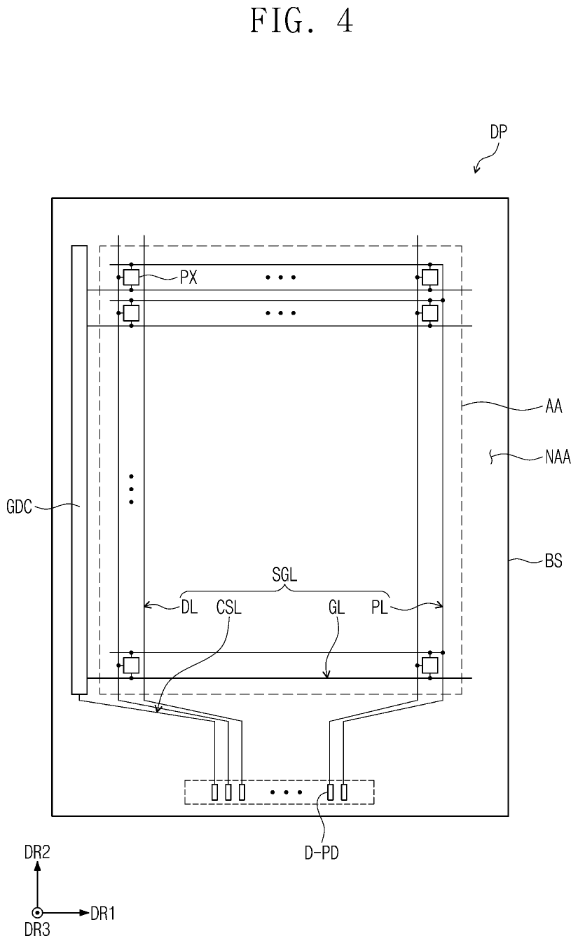

FIG. 4 is a schematic plan view of the display panel DP according to an embodiment of the disclosure.

Referring to FIG. 4, the display panel DP may include the base layer BS, the pixels PX, signal lines SGL, a driving circuit GDC, and pads D-PD electrically connected to the pixels PX.

The base layer BS may be a base surface for arranging elements and lines of the display panel DP on a plane parallel to the first direction DR1 and the second direction DR2. The front surface of the base layer BS may be divided into the display region AA and the non-display region NAA of the display panel DP described above.

The display region AA may include pixels PX arranged therein to display an image. The non-display region NAA may be adjacent to the display region AA and a region on which an image is not displayed. The non-display region NAA may include the driving circuit GDC to drive the pixels PX, some signal lines SGL, and the pads D-PD.

Each of the pixels PX may include a light emitting element, transistors (e.g., switching transistors, driving transistors, etc.) electrically connected to the light emitting element, and a pixel driving circuit including at least one capacitor. The pixels PX may emit light corresponding to an electrical signal applied to each of the pixels PX to display an image in the display region AA.

The signal lines SGL may include gate lines GL, data lines DL, power lines PL, and control signal lines CSL. Each of the gate lines GL and the data lines DL may be electrically connected to a corresponding pixel among the pixels PX. The gate lines GL may extend in the first direction DR1 and may be electrically connected to the driving circuit GDC, and the data lines DL may extend in the second direction DR2 to be insulated from the gate lines GL while crossing the gate lines GL when viewed in a plan view. The power line PL may be electrically connected to the pixels PX. The control signal line CSL may be electrically connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to a pixel driving circuit.

The pads D-PD may be disposed adjacent to a lower end of the non-display region NAA. The pads D-PD may be spaced apart from each other in the first direction DR1. The pads D-PD may be parts electrically connected to a flexible circuit board provided on the display panel DP. Each of the pads D-PD may be connected to a relevant signal line of the signal lines SGL, and may be electrically connected to the pixels PX through the signal lines SGL.

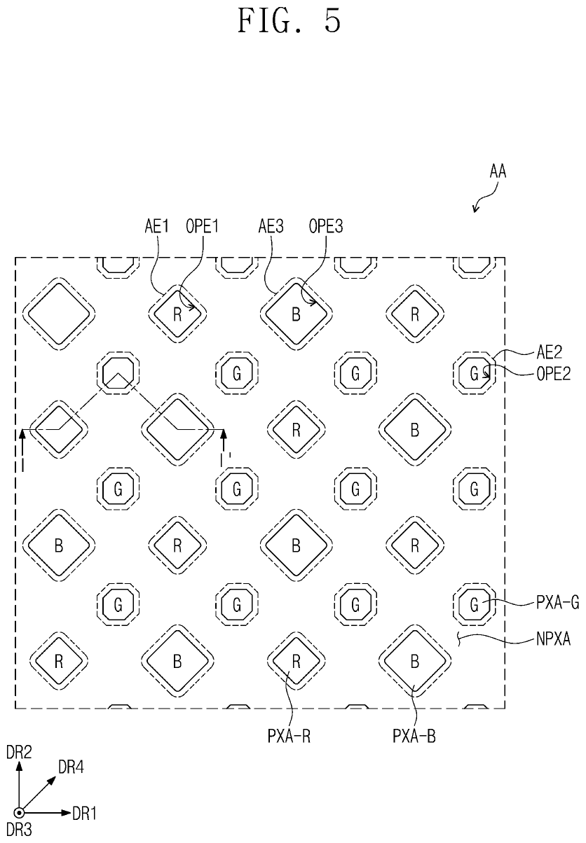

FIG. 5 is an exploded schematic plan view of the display region AA according to an embodiment of the disclosure. FIG. 5 is an enlarged view illustrating the display region AA of the display panel DP (see FIG. 4) when viewed from above the display surface DS (see FIG. 1).

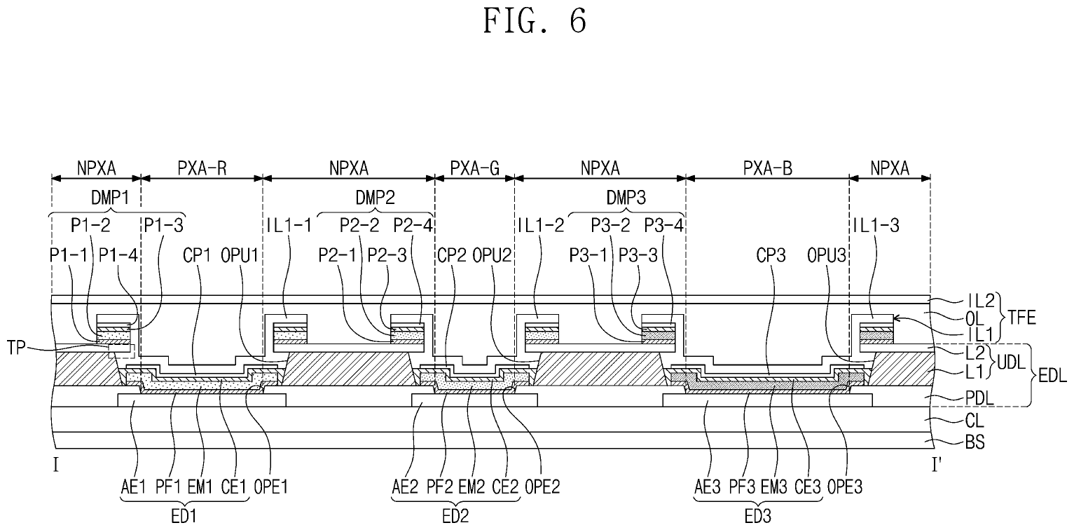

Referring to FIG. 5, the display region AA may include light emitting regions PXA-R, PXA-G, and PXA-B and a non-light emitting region NPXA surrounding the light emitting regions PXA-R, PXA-G, and PXA-B. Each of the light emitting regions PXA-R, PXA-G, and PXA-B may correspond to regions for output light provided from light emitting elements ED1, ED2, and ED3 (see FIG. 6), respectively. FIG. 5 illustrates first electrodes AE1, AE2, and AE3 disposed to correspond to the light emitting regions PXA-R, PXA-G, and PXA-B of components of the light emitting elements ED1, ED2, and ED3 (see FIG. 6).

The light emitting regions PXA-R, PXA-G, and PXA-B may include first to third light emitting regions PXA-R, PXA-G, and PXA-B. The first to third light emitting regions PXA-R, PXA-G, and PXA-B may be classified based on the color of light output toward the outside of the display device DD (see FIG. 1).

The first to third light emitting regions PXA-R, PXA-G, and PXA-B may provide first to third color lights having mutually different colors, respectively. For example, the first to third color lights may be red light, green light, and blue light, respectively. However, the colors of light output through the first to third light emitting regions PXA-R, PXA-G, and PXA-B are not limited to the above examples.

The first to third light emitting regions PXA-R, PXA-G, and PXA-B may be defined as regions, which are exposed through relevant light emitting openings OPE1, OPE2, and OPE3, of top surfaces of the first electrodes AE1, AE2, and AE3. The light emitting openings OPE1, OPE2, and OPE3 may be defined in a lower pixel defining layer PDL (see FIG. 6) to cover some of the first electrodes AE1, AE2, and AE3.

The non-light emitting region NPXA may surround the first to third light emitting regions PXA-R, PXA-G, and PXA-B. The non-light emitting region NPXA may correspond to a region in which the lower pixel defining layer PDL (see FIG. 6) is disposed. The non-light emitting region NPXA may set the boundary between the first to third light emitting regions PXA-R, PXA-G, and PXA-B to prevent colors from being mixed with each other among the first to third light emitting regions PXA-R, PXA-G, and PXA-B.

Multiple ones of each of the first to third light emitting regions PXA-R, PXA-G, and PXA-B may be provided so as to have a specific arrangement form in the display region AA and may be repeatedly disposed. FIG. 5 illustrates an arrangement of the first to third light emitting regions PXA-R, PXA-G, and PXA-B.

For example, referring to FIG. 5, first light emitting regions PXA-R and third light emitting regions PXA-B may be alternately arranged in the first direction DR1 to form a ‘first group’. The second light emitting regions PXA-G may be arranged in the first direction DR1 to form a ‘second group’. The second light emitting regions PXA-G in the second group may be arranged to be offset from the first and third light emitting regions PXA-R and PXA-B in the first group in the first direction DR1 and the second direction DR2. Multiple ones of each of the ‘first group’ and the ‘second group’ may be provided and may be alternately arranged in the second direction DR2.

The second light emitting regions PXA-G may be disposed to be spaced apart from the first light emitting regions PXA-R adjacent thereto or the third light emitting regions PXA-B adjacent thereto in a fourth direction DR4. A fourth direction DR4 may be defined as a diagonal direction crossing each of the first direction DR1 and the second direction DR2, on a plane defined by the first direction DR1 and the second direction DR2.

As illustrated in FIG. 5, the first to third light emitting regions PXA-R, PXA-G, and PXA-B may have a PENTILE™ arrangement. However, the arrangement of the first to third light emitting regions PXA-R, PXA-G, and PXA-B is illustrated in FIG. 5 by way of example, and the arrangement of the first to third light emitting regions PXA-R, PXA-G, and PXA-B may be designed in various manners, depending on the light emitting efficiency, the area of the display region AA, or the resolution of the display device DD (see FIG. 1). For example, the first to third light emitting regions PXA-R, PXA-G, and PXA-B may have a stripe arrangement or a diamond Pixel™ arrangement.

Each of the first to third light emitting regions PXA-R, PXA-G, and PXA-B may have various shapes in a plan view. For example, each of the first to third light emitting regions PXA-R, PXA-G, and PXA-B may have a polygonal shape, a circular shape, or an oval shape. The first to third light emitting regions PXA-R, PXA-G, and PXA-B may have the same shape, or may have at least partially different shapes, when viewed in a plan view. FIG. 5 illustrates the first light emitting regions PXA-R and third light emitting regions PXA-B having a square (or diamond), and the second light emitting regions PXA-G having an octagonal shape, when viewed in a plan view.

At least some of the first to third light emitting regions PXA-R, PXA-G, and PXA-B may have mutually different areas, when viewed in a plan view. For example, the area of the first light emitting region PXA-R to output red light may be larger than the area of the second light emitting region PXA-G to output green light and smaller than the area of the third light emitting region PXA-B to output blue light. However, the relationship in size between the first to third light emitting regions PXA-R, PXA-G, and PXA-B is not limited to the above relationship. The relationship in size may be varied depending on the design of the display panel DP (see FIG. 4). For example, the first to third light emitting regions PXA-R, PXA-G, and PXA-B may have mutually different areas, when viewed in a plan view.

FIG. 6 is a schematic cross-sectional view of the display panel DP, according to an embodiment of the disclosure. FIG. 6 illustrates a cross-sectional view of the display panel DP taken along line I-I′ of FIG. 5.

The display panel DP may include the base layer BS, the circuit layer CL, the display element layer EDL, and the encapsulation layer TFE sequentially stacked on each other. The above-described description may be applied to each component of the display panel DP.

The display element layer EDL may include the light emitting elements ED1, ED2, and ED3, the lower pixel defining layer PDL, an upper pixel defining layer UDL, capping patterns CP1, CP2, and CP3, and dummy patterns DMP1, DMP2, and DMP3. The light emitting elements ED1, ED2, and ED3 may be disposed to correspond to the light emitting regions PXA-R, PXA-G, and PXA-B, and FIG. 6 illustrates cross-sections of the first to third light emitting elements ED1, ED2, and ED3 respectively, to correspond to the first to third light emitting regions PXA-R, PXA-G, and PXA-B.

Each of the first to third light emitting elements ED1, ED2, and ED3 may include a relevant one of the first electrodes AE1, AE2, and AE3, a relevant one of protective layers PF1, PF2, and PF3 (hereinafter, referred to as the first to third protective layers), a relevant one of light emitting patterns EM1, EM2, and EM3 (hereinafter, referred to as the first to third light emitting patterns), and a relevant one of second electrodes CE1, CE2, and CE3.

The first electrodes AE1, AE2, and AE3 and the lower pixel defining layer PDL of the first to third light emitting elements ED1, ED2, and ED3 may be disposed on the circuit layer CL. The first electrodes AE1, AE2, and AE3 of the first to third light emitting elements ED1, ED2, and ED3 may be disposed to be spaced apart from each other on the circuit layer CL. Each of the first electrodes AE1, AE2, and AE3 may include a conductive layer, and may have a single-layer or multi-layer structure. The first electrodes AE1, AE2, and AE3 having a multi-layer structure will be described in detail later.

The first to third light emitting openings OPE1, OPE2, and OPE3 may be defined in the lower pixel defining layer PDL. At least a portion of the first electrode AE1 of the first light emitting element ED1 may be exposed through the first light emitting opening OPE1, which may correspond to the first light emitting region PXA-R. At least a portion of the first electrode AE2 of the second light emitting element ED2 may be exposed through the second light emitting opening OPE2, which may correspond to the second light emitting region PXA-G. At least a portion of the first electrode AE3 of the third light emitting element ED3 may be exposed through the third light emitting opening OPE3, which may correspond to the third light emitting region PXA-B.

The lower pixel defining layer PDL may include an inorganic insulating material. For example, the lower pixel defining layer PDL may include silicon nitride (SiNx). However, in case that the lower pixel defining layer PDL has insulating properties, the material included in the lower pixel defining layer PDL is not limited to the above example. The lower pixel defining layer PDL may be interposed between the first electrodes AE1, AE2, and AE3 and the upper pixel defining layer UDL to block the upper pixel defining layer UDL, which has a conductive property, from being electrically connected to the first electrodes AE1, AE2, and AE3.

Each of the first to third light emitting elements ED1, ED2, and ED3 may include a corresponding one of the first to third protective layers PF1, PF2, and PF3. Each of the first to third protective layers PF1, PF2, and PF3 may be disposed on a corresponding one of the first electrodes AE1, AE2, and AE3 of the first to third light emitting elements ED1, ED2, and ED3. The first protective layer PF1 may overlap the first light emitting region PXA-R, the second protective layer PF2 may overlap the second light emitting region PXA-G, and the third protective layer PF3 may overlap the third light emitting region PXA-B.

The first protective layer PF1, the second protective layer PF2, and the third protective layer PF3 may overlap the first light emitting opening OPE1, the second light emitting opening OPE2, and the third light emitting opening OPE3, respectively. According to an embodiment, the first protective layer PF1 may cover an inner side surface of the lower pixel defining layer PDL defining the first light emitting opening OPE1. The second protective layer PF2 may cover an inner side surface of the lower pixel defining layer PDL defining the second light emitting opening OPE2. The third protective layer PF3 may cover an inner side surface of the lower pixel defining layer PDL defining the third light emitting opening OPE3.

In the process of manufacturing the display panel DP, the first to third protective layers PF1, PF2, and PF3 may cover the first electrodes AE1, AE2, and AE3 exposed to the outside after etching the upper pixel defining layer UDL and the lower pixel defining layer PDL. Each of the first to third protective layers PF1, PF2, and PF3 may contact the uppermost layers of the first electrodes AE1, AE2, and AE3 overlapping the first to third protective layers PF1, PF2, and PF3, respectively. The first to third protective layers PF1, PF2, and PF3 may supplement the functions of the upper layers of the first electrodes AE1, AE2, and AE3 exposed to the outside in the etching process, respectively, and may prevent the first electrodes AE1, AE2, and AE3 from being damaged through a subsequent process.

Each of the first to third protective layers PF1, PF2, and PF3 may include titanium oxide TiOx. The titanium oxide TiOx may be a material having a large work function. For example, the work function of the titanium oxide TiOx may be about 5.8 eV. Therefore, the first to third protective layers PF1, PF2, and PF3 including the titanium oxide TiOx may have a hole injection property substantially the same as or similar to the indium tin oxide (ITO) layer included in the first electrodes AE1, AE2, and AE3. Accordingly, the first to third protective layers PF1, PF2, and PF3 including the titanium oxide TiOx may prevent damage to the first electrodes AE1, AE2, and AE3 during the manufacturing process of the display panel DP and may not degrade driving characteristics of the first electrodes AE1, AE2, and AE3.

The titanium oxide TiOx may be a material having lower electrical conductivity. Accordingly, even if the first to third protective layers PF1, PF2, and PF3 contact the upper pixel defining layer UDL having the conductive property in the process of depositing the first to third protective layers PF1, PF2, and PF3, current may be prevented from leaking through the first to third protective layers PF1, PF2, and PF3.

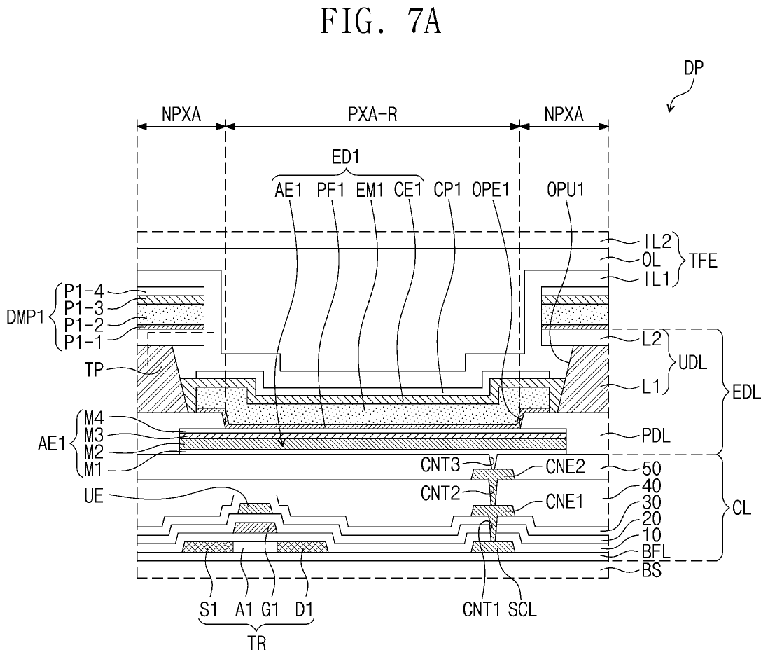

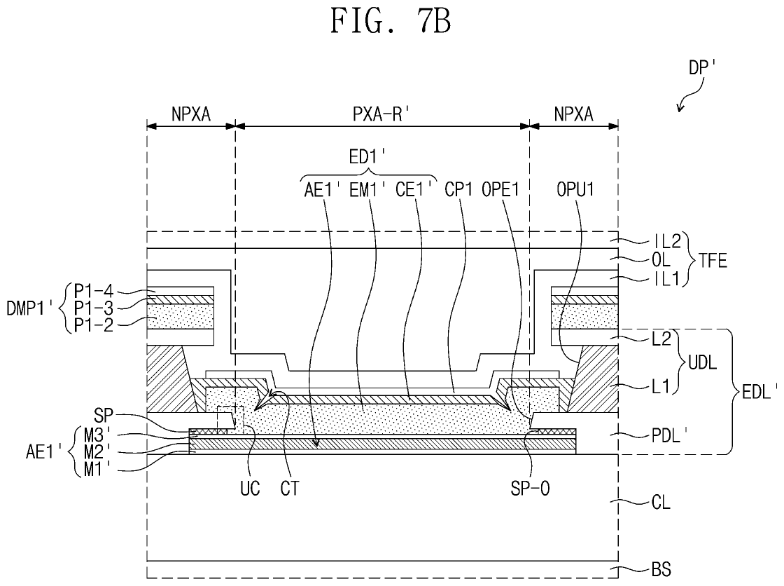

Since the first to third protective layers PF1, PF2, and PF3 are disposed on the display element layer EDL, the arrangement of a sacrificial pattern SP (see FIG. 7B) to be described later may be omitted. In other words, the arrangement of the sacrificial pattern SP (see FIG. 7B) disposed to protect the first electrode of the light emitting element and having an opening corresponding to the light emitting regions may be omitted. Since the first to third protective layers PF1, PF2, and PF3 do not degrade the driving characteristics of the first electrodes AE1, AE2, and AE3, the first to third protective layers PF1, PF2, and PF3 may overlap the light emitting regions PXA-R, PXA-G, and PXA-B, and the first to third protective layers PF1, PF2, and PF3 do not need to be patterned to have openings corresponding to the light emitting regions PXA-R, PXA-G, and PXA-B.

As the arrangement of the sacrificial pattern SP (see FIG. 7B) may be omitted, an undercut part may be prevented from being formed by the sacrificial pattern SP (see FIG. 7B). Accordingly, the first to third light emitting patterns EM1, EM2, and EM3 and the second electrodes CE1, CE2, and CE3 disposed on the first electrodes AE1, AE2, and AE3 may be prevented from being damaged by the undercut part. The details thereof will be described later.

Each of the first to third light emitting patterns EM1, EM2, and EM3 may be disposed on a corresponding one of the first to third protective layers PF1, PF2, and PF3, respectively. Each of the first to third light emitting patterns EM1, EM2, and EM3 may include a light emitting layer including a light emitting material. Each of the first to third light emitting patterns EM1, EM2, and EM3 may further include a light emitting functional layer disposed on an upper portion and/or a lower portion of the light emitting layer. For example, each of the first to third light emitting patterns EM1, EM2, and EM3 may further include a hole injection layer or a hole transport layer interposed between a relevant one of the first electrodes AE1, AE2 and AE3, and the light emitting layer, or may further include an electron injection layer or an electron transport layer interposed between the light emitting layer and a relevant one of the second electrodes CE1, CE2, and CE3.

Each of the first to third light emitting patterns EM1, EM2, and EM3 may provide color light. For example, the first light emitting pattern EM1 may provide red light, and the first light emitting element ED1 may output red light through the first light emitting region PXA-R. The second light emitting pattern EM2 may provide green light, and the second light emitting element ED2 may output green light through the second light emitting region PXA-G. The third light emitting pattern EM3 may provide blue light, and the third light emitting element ED3 may output blue light through the third light emitting region PXA-B. However, the color of the light emitted from the first to third light emitting elements ED1, ED2, and ED3 is not limited thereto.

Each of the second electrodes CE1, CE2, and CE3 in the first to third light emitting elements ED1, ED2, and ED3 may be disposed on a corresponding one of the first to third light emitting patterns EM1, EM2, and EM3. The second electrodes CE1, CE2, and CE3 in the first to third light emitting elements ED1, ED2, and ED3 may be spaced apart from each other while interposing the upper pixel defining layer UDL interposed therebetween, when viewed in a plan view. The upper pixel defining layer UDL may surround the second electrodes CE1, CE2, and CE3 of the first to third light emitting elements ED1, ED2, and ED3, when viewed in a plan view.

The upper pixel defining layer UDL may be disposed on the lower pixel defining layer PDL. The upper pixel defining layer UDL may include layers L1 and L2. The upper pixel defining layer UDL may include the first upper layer L1 disposed on the lower pixel defining layer PDL and the second upper layer L2 disposed on the first upper layer L1.

First to third upper openings OPU1, OPU2, and OPU3 may be defined in the upper pixel defining layer UDL. Each of the first to third upper openings OPU1, OPU2, and OPU3 may overlap a corresponding one of the first to third light emitting openings OPE1, OPE2, and OPE3. Each of the first to third upper openings OPU1, OPU2, and OPU3 may form an integral opening space with an overlapping light emitting opening among the first to third light emitting openings OPE1, OPE2, and OPE3.

The first to third upper openings OPU1, OPU2, and OPU3 may be defined by inner side surfaces, which are disposed to be adjacent to the first to third light emitting openings OPE1, OPE2, and OPE3, of the first upper layer L1. A planar area of each of the first to third upper openings OPU1, OPU2, and OPU3 may be larger than a planar area of an overlapping light emitting opening among the first to third light emitting openings OPE1, OPE2, and OPE3. Accordingly, inner side surfaces of the first upper layer L1 may be disposed on the top surface of the lower pixel defining layer PDL.

The second upper layer L2 may cover a top surface of the first upper layer L1. Each of inner side surfaces of second upper layers L2 may protrude further toward the center of overlapping upper opening among the upper openings OPU1, OPU2, and OPU3, from the inner side surface of the first upper layer L1 adjacent to the second upper layer L2. For example, the inner side surface of the second upper layer L2 adjacent to the first upper opening OPU1 may protrude further toward the center of the first upper opening OPU1 from the inner side surface of the first upper layer L1 defining the first upper opening OPU1. Accordingly, a tip part TP may be formed in the upper pixel defining layer UDL.

The first to third light emitting patterns EM1, EM2, and EM3 of the first to third light emitting elements ED1, ED2, and ED3 may be formed by patterning the light emitting layer through the tip part TP formed in the upper pixel defining layer UDL. The first light emitting pattern EM1 may be disposed inside the first light emitting opening OPEL and the first upper opening OPU1. The second light emitting pattern EM2 may be disposed inside the second light emitting opening OPE2 and the second upper opening OPU2. The third light emitting pattern EM3 may be disposed inside the third light emitting opening OPE3 and the third upper opening OPU3.

The first to third light emitting patterns EM1, EM2, and EM3 may be patterned and deposited through the tip part TP formed in the upper pixel defining layer UDL in units of the light emitting regions PXA-R, PXA-G, and PXA-B. For example, in the deposition process for forming the first light emitting pattern EM1, the light emitting layer may be deposited using an open mask, and the light emitting layer may be deposited through the tip part TP formed in the upper pixel defining layer UDL in the form of the first light emitting pattern EM1 separated to correspond to the first light emitting region PXA-R.

In case of patterning the first light emitting pattern EM1 using a fine metal mask (FMM), a support spacer protruding to support the fine metal mask may be provided. There may be limitations in forming fine deposition openings inside the fine metal mask. Accordingly, fine-sized light-emitting patterns EM1, EM2, and EM3 may be difficult to form as the fine metal mask may be spaced above the height of the spacer from the deposition surface on which the light-emitting patterns are formed, and the fine property in the deposition opening may be deteriorated. In other words, in case that the fine metal mask (FMM) is used for the deposition of light emitting patterns, there may be limitations in the manufacture of display panels that implement higher resolution. As the fine metal mask makes contact with the spacer, foreign substances may remain in the spacer after the light-emitting patterns forming process, or the spacer may be damaged by the imprint of the fine metal mask. Accordingly, process reliability of the display panel may be deteriorated.

However, according to an embodiment, as the display panel DP includes the upper pixel defining layer UDL forming the tip part TP and having the conductivity, the light emitting patterns EM1, EM2, and EM3 having fine sizes may be easily formed in the display panel DP without using the fine metal mask. Accordingly, the light emitting layer may be patterned without additionally providing a supporting spacer on the upper pixel defining layer UDL, and the reliability in process of the display panel DP may be improved. As the light emitting patterns EM1, EM2, and EM3 having fine sizes are formed, it may be possible to manufacture the display panel DP capable of implementing the higher resolution. As the light emitting elements ED1, ED2, and ED3 may be physically separated from each other by the upper pixel defining layer UDL, the current may be prevented from leaking or a driving error may be prevented.

The second electrodes CE1, CE2, and CE3 of the first to third light emitting elements ED1, ED2, and ED3 may be formed by patterning the conductive layer through the tip part TP formed in the upper pixel defining layer UDL. The second electrode CE1 of the first light emitting element ED1 may be disposed in the first upper opening OPU1 and may contact the inner side surface of the first upper layer L1 defining the first upper opening OPU1. The second electrode CE2 of the second light emitting element ED2 may be disposed in the second upper opening OPU2 and may contact the inner side surface of the first upper layer L1 defining the second upper opening OPU2. The second electrode CE3 of the third light emitting element ED3 may be disposed in the third upper opening OPU3 and may contact the inner side surface of the first upper layer L1 defining the third upper opening OPU3.

The first upper layer L1 and the second upper layer L2 may include different materials from each other, and accordingly, the etching rates may be different. The etching rate of the first upper layer L1 may be greater than the etching rate of the second upper layer L2. In other words, the first upper layer L1 may include a material having an etching selectivity higher than that of the second upper layer L2. The inner side surface of the second upper layer L2 may further protrude from the inner side surface of the first upper layer L1 due to the difference in etching rate between the first upper layer L1 and the second upper layer L2. Accordingly, the upper pixel defining layer UDL may include the tip part TP.

The first upper layer L1 and the second upper layer L2 may have conductivity. Each of the first upper layer L1 and the second upper layer L2 may include a metal material. The conductivity of the first upper layer L1 may be higher than the conductivity of the second upper layer L2. For example, the first upper layer L1 may include aluminum (Al), molybdenum (Mo), or an alloy containing them, and the second upper layer L2 may include titanium (Ti). However, materials of the first upper layer L1 and the second upper layer L2 are not limited to the above example.

The thickness of the first upper layer L1 may be thinner than the thickness of the second upper layer L2. Accordingly, the second electrodes CE1, CE2, and CE3 of the first to third light emitting elements ED1, ED2, and ED3 may stably contact the first upper layer L1.

As the second electrodes CE1, CE2, and CE3 of the first to third light emitting elements ED1, ED2, and ED3 stably contact the first upper layer L1 of the upper pixel defining layer UDL, the second electrodes CE1, CE2, and CE3 may receive a bias voltage applied to the upper pixel defining layer UDL. In other words, the second electrodes CE1, CE2, and CE3 may be connected to the upper pixel defining layer UDL to receive a common voltage. As the first upper layer L1 having high electrical conductivity has a thicker thickness and makes contact with the second electrodes CE1, CE2, and CE3, driving resistance of the first to third light emitting elements ED1, ED2, and ED3 may be reduced, and a common driving voltage may be uniformly provided to the first to third light emitting elements ED1, ED2, and ED3. Accordingly, the light emitting efficiency and the lifespan of the display panel DP may be increased.

In other words, the second upper layer L2 may include a material having a reflectance lower than the reflectance of the first upper layer L1. Since the second upper layer L2 is disposed on the upper portion of the upper pixel defining layer UDL, the reflectance of light incident from the upper portion of the display panel DP toward the display panel DP may be reduced. Accordingly, the display quality of the display panel DP may be improved.

Each of the capping patterns CP1, CP2, and CP3 may be disposed on a corresponding one of the second electrodes CE1, CE2, and CE3 of the first to third light emitting elements ED1, ED2, and ED3, respectively. The capping patterns CP1, CP2, and CP3 may be formed by patterning an insulating layer by the tip part TP formed on the upper pixel defining layer UDL. However, according to an embodiment, the capping patterns CP1, CP2, and CP3 may be omitted.

The capping patterns CP1, CP2, and CP3 may have a single-layer or multi-layer structure. The capping patterns CP1, CP2, and CP3 may include at least one of an inorganic layer and an organic layer. For example, the capping patterns CP1, CP2, and CP3 may protect the first to third light emitting elements ED1, ED2, and ED3 disposed under the capping patterns CP1, CP2, and CP3. The capping patterns CP1, CP2, and CP3 may be insulating layers having a specific refractive index. Accordingly, light extraction efficiency of the first to third light emitting elements ED1, ED2, and ED3 may be improved.

The dummy patterns DMP1, DMP2, and DMP3 may be disposed on the upper pixel defining layer UDL. The dummy patterns DMP1, DMP2, and DMP3 may include the first to third dummy patterns DMP1, DMP2, and DMP3 surrounding the first to third light emitting elements ED1, ED2, and ED3 respectively when viewed in a plan view.

Each of the first to third dummy patterns DMP1, DMP2, and DMP3 may include pattern parts sequentially stacked on each other in a thickness direction. The first dummy pattern DMP1 may include a (1-1)-th pattern part P1-1 to a (1-4)-th pattern part P1-4, which are sequentially stacked. The second dummy pattern DMP2 may include a (2-1)-th pattern part P2-1 to a (2-4)-th pattern part P2-4, which are sequentially stacked. The third dummy pattern DMP3 may include a (3-1)-th pattern part P3-1 to a (3-4)-th pattern part P3-4, which are sequentially stacked.

The (1-1)-th pattern part, the (2-1)-th pattern part P2-1, and the (3-1)-th pattern part P3-1 may be disposed on the second upper layer L2 serving as the same layer. The (1-1)-th pattern part, the (2-1)-th pattern part P2-1, and the (3-1)-th pattern part P3-1 may include a material the same as a material of the protective layers PF1, PF2, and PF3. The (1-1)-th pattern part, the (2-1)-th pattern part P2-1, and the (3-1)-th pattern part P3-1 may be formed to be separated from the protective layers PF1, PF2, and PF3 by the tip part TP of the upper pixel defining layer UDL in the deposition process for forming the protective layers PF1, PF2, and PF3.

The (1-2)-th pattern part P1-2 may be disposed on the (1-1)-th pattern part P1-1. The (1-2)-th pattern part P1-2 may include a material the same as a material of the first light emitting pattern EM1. The (1-2)-th pattern part P1-2 may be formed to be separated from the first light emitting pattern EM1 by the tip part TP of the upper pixel defining layer UDL in the deposition process for forming the first light emitting pattern EM1.

The (2-2)-th pattern part P2-2 may be disposed on the (2-1)-th pattern part P2-1. The (2-2)-th pattern part P2-2 may include a material the same as a material of the second light emitting pattern EM2. The (2-2)-th pattern part P2-2 may be formed to be separated from the second light emitting pattern EM2 by the tip part TP of the upper pixel defining layer UDL in the deposition process for forming the second light emitting pattern EM2.

The (3-2)-th pattern part P3-2 may be disposed on the (3-1)-th pattern part P3-1. The (3-2)-th pattern part P3-2 may include a material the same as a material of the third light emitting pattern EM3. The (3-2)-th pattern part P3-2 may be formed to be separated from the third light emitting pattern EM3 by the tip part TP of the upper pixel defining layer UDL in the deposition process for forming the third light emitting pattern EM3.

The (1-3)-th pattern part P1-3, the (2-3)-th pattern part P2-3 and the (3-3)-th pattern part P3-3 may be disposed on a corresponding one of the (1-2)-th pattern part P1-2, the (2-2)-th pattern part P2-2, and the (3-2)-th pattern part P3-2. The (1-3)-th pattern part P1-3, the (2-3)-th pattern part P2-3, and the (3-3)-th pattern part P3-3 may include a material the same as a material of the second electrodes CE1, CE2, and CE3. The (1-3)-th pattern part P1-3, the (2-3)-th pattern part P2-3, and the (3-3)-th pattern part P3-3 may be formed to be separated from the second electrodes CE1, CE2, and CE3 by the tip part TP of the upper pixel defining layer UDL in the deposition process for forming the second electrodes CE1, CE2, and CE3.

The (1-4)-th pattern part P1-4, the (2-4)-th pattern part P2-4, and the (3-4)-th pattern part P3-4 may be disposed on a corresponding one of the (1-3)-th pattern part P1-3, the (2-3)-th pattern part P2-3, and the (3-3)-th pattern part P3-3. The (1-4)-th pattern part P1-4, the (2-4)-th pattern part P2-4, and the (3-4)-th pattern part P3-4 may include a material the same as a material of the capping patterns CP1, CP2, and CP3. The (1-4)-th pattern part P1-4, the (2-4)-th pattern part P2-4, and the (3-4)-th pattern part P3-4 may be formed to be separated from the capping patterns CP1, CP2, and CP3 by the tip part TP of the upper pixel defining layer UDL in the deposition process for forming the capping patterns CP1, CP2, and CP3.

The encapsulation layer TFE may be disposed on the display element layer EDL. The encapsulation layer TFE may include a first inorganic layer IL1, an organic layer OL, and a second inorganic layer IL2 sequentially stacked. A first inorganic layer IL1 may cover the first to third light emitting elements ED1, ED2, and ED3 and the first to third dummy patterns DMP1, DMP2, and DMP3. A portion of the first inorganic layer IL1 may be disposed inside the upper openings OPU1, OPU2, and OPU3.

The first inorganic layer IL1 may include first to third inorganic patterns IL1-1, IL1-2, and IL1-3 that overlap the first to third light emitting elements ED1, ED2, and ED3, respectively. The first to third inorganic patterns IL1-1, IL1-2, and IL1-3 may be spaced apart from each other on a region overlapping the upper pixel defining layer UDL.

The organic layer OL may be disposed on the first inorganic layer IL1, may cover the stepped first inorganic layer IL1, and may provide a flat top surface. The organic layer OL may cover the first to third inorganic patterns IL1-1, IL1-2, and IL1-3 spaced apart from each other.

The second inorganic layer IL2 may be disposed on the organic layer OL. The second inorganic layer IL2 may be formed as an integral layer overlapping the first to third light emitting elements ED1, ED2, and ED3.

The first inorganic layer IL1 and the second inorganic layer IL2 may protect the light emitting elements ED1, ED2, and ED3 from moisture and/or oxygen. Each of the first inorganic layer IL1 and the second inorganic layer IL2 may include a silicon nitride, a silicon oxynitride, a silicon oxide, a titanium oxide, or an aluminum oxide, but the disclosure is not particularly limited thereto.

The organic layer OL may protect the light emitting elements ED1, ED2, and ED3 from foreign substances such as dust particles. The organic layer OL may include an acrylic compound or an epoxy compound, but is not particularly limited thereto.

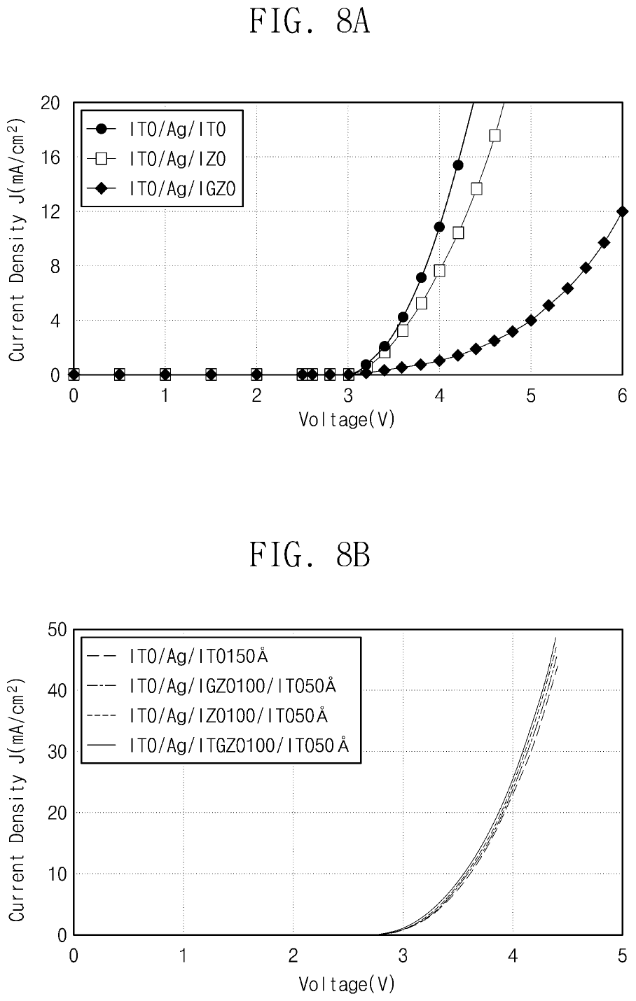

FIG. 7A is a schematic cross-sectional view of the display panel DP, according to an embodiment of the disclosure. FIG. 7B is a schematic cross-sectional view of the display panel DP, according to a comparative example of the disclosure. FIGS. 8A and 8B schematically illustrate voltage-current graphs based on configurations of the first electrode AE1.

FIG. 7A is an enlarged cross-sectional view of the first light emitting region PXA-R of light emitting regions PXA-R, PXA-G, and PXA-B, and FIG. 7B is an enlarged cross-sectional view corresponding to a first light emitting region PXA-R′ according to a comparative example.

Referring to FIG. 7A, the circuit layer CL may be disposed on the base layer BS. The circuit layer CL may include a buffer layer BFL, a transistor TR, a connection signal line SCL, connection electrodes CNE1 and CNE2, and first to fifth insulating layers 10 to 50. The stack structure of the circuit layer CL illustrated in FIG. 7A is provided only for the illustrative purpose, and may be varied depending on the configuration of the pixel driving circuit.

The circuit layer CL may be disposed on the base layer BS. The buffer layer BFL may improve a coupling force between the base layer BS and a semiconductor pattern of the transistor TR. The buffer layer BFL may include an inorganic layer. For example, the buffer layer BFL may include a silicon oxide layer and a silicon nitride layer, and the silicon oxide layer and the silicon nitride layer may be stacked on each other. However, the material of the buffer layer BFL is not limited to the above example.

The semiconductor pattern of the transistor TR may be disposed on the buffer layer BFL. The semiconductor pattern may include polysilicon, amorphous silicon, and/or a metal oxide. The material included in the semiconductor pattern is not limited to any one particular embodiment as long as the material has semiconductor characteristics. Although FIG. 7A illustrates a portion of the semiconductor pattern, the semiconductor pattern may be disposed in a specific pattern throughout the light emitting regions PXA-R, PXA-G, and PXA-B (see FIG. 6).

The semiconductor pattern of the transistor TR may include regions having mutually different electrical properties depending on whether doped or whether a metal oxide is reduced. A doped region or reduced region of the semiconductor pattern may have a higher conductivity to serve as an electrode or a signal line of the transistor TR. The region showing a higher conductivity in the semiconductor pattern may correspond to a source region S1 and a drain region D1 of the transistor TR. A region, which is neither doped nor reduced, or a region which is doped at a concentration lighter than a concentration of the source and drain regions S1 and D1, may show a lower conductivity, and may correspond to an active region A1 of the transistor TR.

The connection signal line SCL may be disposed on the buffer layer BFL. The connection signal line SCL may be formed from a semiconductor pattern. The connection signal line SCL may be connected to the drain region D1 when viewed in a plan view.

Each of the first to fifth insulating layers 10 to 50 may include at least one of an inorganic layer and an organic layer. For example, the inorganic layer may include at least one of an aluminum oxide, a titanium oxide, a silicon oxide, a silicon oxynitride, a zirconium oxide, and a hafnium oxide. The organic layer may include at least one of an acrylic resin, a methacrylic resin, a polyisoprene, a vinyl resin, an epoxy resin, a urethane resin, a cellulose resin, a siloxane resin, a polyamide resin, and a perylene resin.

The first insulating layer 10 may be disposed on the buffer layer BFL. The first insulating layer 10 may cover a semiconductor pattern of the transistor TR. A gate electrode G1 of the transistor TR may be disposed on the first insulating layer 10. The gate electrode G1 may overlap the active region A1, when viewed in a plan view. According to an embodiment, the gate electrode G1 may function as a mask in a process of doping a semiconductor pattern.

The insulating layer 20 may be disposed on the first insulating layer 10 and may cover the gate electrode G1. An upper electrode UE may be disposed on the second insulating layer 20. The upper electrode UE may overlap the gate electrode G1 to form a capacitor.

The insulating layer 30 may be disposed on the second insulating layer 20 and may cover the upper electrode UE. The first connection electrode CNE1 of the connection electrodes CNE1 and CNE2 may be disposed on the third insulating layer 30. The first connection electrode CNE1 may be connected to the connection signal line SCL through a contact hole CNT1 formed through the first to third insulating layers 10 to 30.

The insulating layer 40 may be disposed on the third insulating layer 30 and may cover the first connection electrode CNE1. The second connection electrode CNE2 may be disposed on the fourth insulating layer 40. The second connection electrode CNE2 may be connected to the first connection electrode CNE1 through a contact hole CNT2 formed through the fourth insulating layer 40.

The insulating layer 50 may be disposed on the fourth insulating layer 40 and may cover the second connection electrode CNE2. The fifth insulating layer 50 may include an organic layer. The organic layer of the fifth insulating layer 50 may cover the stepped top surface of the components disposed below and may provide a flat surface in an upper portion thereof.

Referring to FIG. 7A, the first light emitting element ED1 may be disposed on the fifth insulating layer 50. The first light emitting element ED1 may include the first electrode AE1, the first protective layer PF1, the first light emitting pattern EM1, and the second electrode CE1 sequentially stacked. The above-described description may be applied to each component of the first light emitting element ED1. The description of the first light emitting element ED1 to be described later may be applied to the second and third light emitting elements ED2 and ED3.

The first electrode AE1 may be connected to the second connection electrode CNE2 through a contact hole CNT3 formed through the fifth insulating layer 50. The first electrode AE1 may be electrically connected to the connection signal line SCL through the first and second connection electrodes CNE1 and CNE2.

The first electrode AE1 may have a multi-layer structure. The first electrode AE1 according to an embodiment may include first to fourth conductive layers M1, M2, M3, and M4.

The first conductive layer M1 may be disposed on the fifth insulating layer 50 of the circuit layer CL. The first conductive layer M1 may be electrically connected to the second connection electrode CNE2 through a contact hole CNT3 formed through the fifth insulating layer 50. The first conductive layer M1 may include a transparent conductive oxide. For example, the first conductive layer M1 may include indium tin oxide (ITO).

The second conductive layer M2 may be disposed on the first conductive layer M1. The second conductive layer M2 may include a metal material having a superior electrical conductivity and lower resistance. The second conductive layer M2 may be a reflective electrode layer, and may improve emission efficiency by reflecting light introduced from the first light emitting pattern EM1. For example, the second conductive layer M2 may include silver (Ag), magnesium (Mg), aluminum (Al), platinum (Pt), palladium (Pd), gold (Au), nickel (Ni), neodymium (Nd), iridium (Ir), chromium (Cr), and/or an alloy thereof.

The third conductive layer M3 may be disposed on the second conductive layer M2. The third conductive layer M3 may include a transparent conductive oxide. For example, the third conductive layer M3 may include a zinc-based conductive oxide such as indium gallium zinc oxide (IGZO), indium zinc oxide (IZO), or indium zinc tin oxide (IZTO).

The third conductive layer M3 may be disposed with a specific thickness on the second conductive layer M2 to function as an etching stopper in the etching process of the upper pixel defining layer UDL and the lower pixel defining layer PDL. In other words, the third conductive layer M3 may function as a hard mask and may protect the second conductive layer M2 during the etching process. For example, the thickness of the third conductive layer M3 may be about 200 Å to about 300 Å, thereby stably protecting the second conductive layer M2.

The fourth conductive layer M4 may be disposed on the third conductive layer M3. The fourth conductive layer M4 may include a transparent conductive oxide. The fourth conductive layer M4 may include indium tin oxide (ITO). In case that the fourth conductive layer M4 is omitted and the conductive layer including the zinc-based oxide is disposed at the uppermost part of the first electrode AE1, hole injection characteristics may be degraded, and thus a driving voltage may be shifted. However, as the fourth conductive layer M4 including indium tin oxide (ITO) is disposed, the driving reliability of the first electrode AE1 may be improved. This may be recognized through current-voltage graphs according to embodiments and comparative examples illustrated in FIGS. 8A and 8B.

Referring to FIG. 8A, a current may be varied depending on the stack structure of the first electrode, in case that the same voltage is applied. For example, the first electrode having the stack structure of ITO/Ag/ITO according to a first embodiment may be driven at a driving voltage lower than a driving voltage of a first electrode having the stack structure of ITO/Ag/IZO according to a first comparative example, and a first electrode having the stack structure of ITO/Ag/IGZO according to a second comparative example. In particular, according to the second comparative example, in which the IGZO layer is disposed on the uppermost part of the first electrode, the driving voltage may be shifted such that the driving characteristic may be degraded. However, according to the first embodiment in which the ITO is disposed on the uppermost part of the first electrode, an excellent driving characteristic is shown, as compared to the first and second comparative examples.

Referring to FIG. 8B, it may be recognized that the driving characteristic is not deteriorated, even if a zinc-based oxide layer is interposed between the AG layer and the ITO layer. For example, according to the second embodiment in which the first electrode has the stack structure of ITO/Ag/IGZO/ITO, the third embodiment in which the first electrode has the stack structure of ITO/Ag/IZO/ITO, and the fourth embodiment in which the first electrode has the stack structure of ITO/Ag/ITGZO/ITO, the driving voltage is not shifted, and a driving characteristic is similar to the driving characteristic according to the first embodiment in which the first electrode has the stack structure of ITO/Ag/ITO. Accordingly, in case that the upper most part layer of the first electrode is the ITO layer, and in case that the zinc-based oxide layer is further disposed, the driving characteristic may not be lowered.

Referring back to FIG. 7A, the fourth conductive layer M4 may have a specific thickness. For example, the thickness of the fourth conductive layer M4 may be about 50 Å to about 100 Å. In case that the fourth conductive layer M4 is less than about 50 Å, the fourth conductive layer M4 and the component disposed under the fourth conductive layer M4 may be damaged by the etching process during the manufacturing process of the display panel DP, thereby reducing the effect of preventing driving deterioration.

According to an embodiment, since the first electrode AE1 includes the first to fourth conductive layers M1, M2, M3, and M4, the first electrode AE1 may be prevented from being damaged by the etching process during the manufacturing process of the display panel DP and may have driving reliability.

The first protective layer PF1 may be disposed on the first electrode AE1. The first protective layer PF1 may contact the fourth conductive layer M4 of the first electrode AE1. The above-described description may be applied to the first protective layer PF1.

The first protective layer PF1 may include titanium oxide TiOx having a large work function. The first protective layer PF1 may have the same or similar hole injection characteristics as that of the indium tin oxide ITO layer. Even in case that a portion of the fourth conductive layer M4 is damaged in the etching process, the function of the fourth conductive layer M4 may be supplemented by disposing the first protective layer PF1.

The first protective layer PF1 may be formed by depositing a titanium layer. The first protective layer PF1 may be formed from the titanium layer patterned by the tip part TP formed on the upper pixel defining layer UDL, and the first protective layer PF1 may be formed in the first light emitting opening OPE1. In the process of forming the first protective layer PF1, the (1-1)-th pattern part P1-1 of the first dummy pattern DMP1 may be separated from the first protective layer PF1 by the tip part TP of the upper pixel defining layer UDL and formed on the upper pixel defining layer UDL.

The first protective layer PF1 including titanium oxide TiOx may have low electrical conductivity. Accordingly, even if the first protective layer PF1 makes contact with the inner side surface of the first upper layer L1 of the upper pixel defining layer UDL, a current may be prevented from leaning by the first protective layer PF1.

The first protective layer PF1 may have a thin thickness. For example, the thickness of the first protective layer PF1 may be about 30 Å to about 50 Å. As the first protective layer PF1 has a thin thickness, a deposition process of the first protective layer PF1 may be easily performed, and a titanium oxide (TiOx) layer may be easily formed in the first protective layer PF1 without a separate heat treatment. The first protective layer PF1 may have an effect of protecting the first electrode AE1, even with a thin thickness.

As the first protective layer PF1 is disposed, the arrangement of the sacrificial pattern SP according to the comparative example shown in FIG. 7B may be omitted. The first protective layer PF1 does not degrade the driving characteristic of the first electrode AE1. Accordingly, the first protective layer PF1 may overlap the first light emitting region PXA-R. Accordingly, a patterning process for exposing the top surface of the first electrode AE1 may not be required, which may be different from the sacrificial pattern SP according to the comparative example. In other words, the first protective layer PF1, which protects the first electrode AE1 and improves driving reliability of the first electrode AE1, may be formed only through a deposition process. Accordingly, the manufacturing process of the display panel DP may be simplified.

Referring to FIG. 7B, a first electrode AE1′ according to the comparative example may include first to third conductive layers M1′, M2′, and M3′. The first conductive layer M1′ may be connected to the connection electrode in the circuit layer CL to be electrically connected to the connection electrode. For example, the first conductive layer M1′ may include indium tin oxide ITO.

The second conductive layer M2′ may be disposed on the first conductive layer M1′. The second conductive layer M2′ may include a material having an excellent conductivity and a lower resistance. The second conductive layer M2′ may be a reflective electrode layer. For example, the second conductive layer M2′ may include at least one of silver (Ag), magnesium (Mg), aluminum (Al), platinum (Pt), palladium (Pd), gold (Au), nickel (Ni), neodymium (Nd), iridium (Ir), chromium (Cr), and the alloy thereof.

The third conductive layer M3′ may be disposed on the second conductive layer M2′. The third conductive layer M3′ may include a transparent conductive material. For example, the third conductive layer M3′ may include indium tin oxide ITO.

According to the comparative example, as the third conductive layer M3′ including ITO is disposed in the first electrode AE1′ without disposing the conductive layer including zinc-based conductive oxides on the second conductive layer M2′, the second conductive layer M2′ may be etched to be damaged together with the third conductive layer M3′, in the process of etching the upper pixel defining layer UDL and the lower pixel defining layer PDL′. Accordingly, the display element layer EDL′ may require a sacrificial pattern SP that prevents damage to the second conductive layer M2′ and the third conductive layer M3′. Therefore, the display element layer EDL′ according to the comparative example may include the sacrificial pattern SP, and the protective layers PF1, PF2, PF3, (see FIG. 6) according to the disclosure may not be disposed in the display element layer EDL′ according to the comparative example.

According to the comparative example, a dummy pattern DMP1′ may be disposed on the upper pixel defining layer UDL. The dummy pattern DMP1′ may include pattern parts corresponding to the (1-2)-th pattern part P1-2, the (1-3)-th pattern part P1-3 and the (1-4)-th pattern part P1-4 according to an embodiment. According to the comparative example, as the protective layer PF1 (see FIG. 7A) is not disposed in the display element layer EDL′, the (1-1)-th pattern part P1-1 (see FIG. 7A) formed in the process of forming the protective layer PF1 (see FIG. 7A) may not be formed in the display panel DP′ according to the comparative example.

The sacrificial pattern SP may include an amorphous transparent conductive oxide. For example, the sacrificial pattern SP may include indium gallium zinc oxide (IGZO) or indium zinc oxide (IZO).

The sacrificial pattern SP may be disposed on the top surface of the first electrode AE1′. An opening SP-O corresponding to the first light emitting opening OPE1 may be defined in the sacrificial pattern SP. The opening SP-O of the sacrificial pattern SP may overlap the first light emitting opening OPEL and may expose a portion of the top surface of the first electrode AE1′.

In the process of etching the upper pixel defining layer UDL and the lower pixel defining layer PDL′ during the manufacturing process of the display panel DP′, the sacrificial pattern SP may be etched to expose the top surface of the first electrode AE1′ after protecting the first electrode AE1′. In other words, the opening SP-O of the sacrificial pattern SP may be formed by etching the sacrificial pattern SP. In case that the sacrificial pattern SP remains corresponding to the first light emitting region PXA-R′, a characteristic in which holes are injected into the first light emitting pattern EM1′ through the first electrode AE1′ may be degraded. Accordingly, the driving voltage of the first light emitting element ED1′ may be shifted to reduce driving reliability.

To prevent the driving voltage of the first light emitting element ED1 from being shifted, the sacrificial pattern SP may be patterned such that the opening SP-O having a planar area larger than that of the first light emitting opening OPE1 is formed in the sacrificial pattern SP. The inner side surface of the pixel defining layer PDL′ defining the first light emitting opening OPE1 may protrude further toward the center of the first electrode AE1 than the inner side surface of the sacrificial pattern SP defining the opening SP-O. When viewed in the cross-sectional view, an under-cut part UC may be formed on the first electrode AE1′ due to the difference in position between the inner side surface of the pixel defining layer PDL′ and the inner side surface of the sacrificial pattern SP.

A first light emitting pattern EM1′ formed on the first electrode AE1′ may be partially recessed or may form a big step difference due to the under-cut part UC by the sacrificial pattern SP and the lower pixel defining layer PDL′. Accordingly, gas may be generated from a region corresponding to the under-cut part UC or a portion of a second electrode CE1′ disposed on the first light emitting pattern EM1′ may be disconnected (see reference sign CT). As the second electrode CE1′ is disconnected (see reference sign CT), the first light emitting element ED1′ according to a comparative example may fail, and the reliability may be degraded.

However, according to an embodiment, in the display element layer EDL, the sacrificial pattern SP having the opening SP-O corresponding to the light emitting region PXA-R′ may be omitted by the protective layer PF1. Accordingly, the under-cut part UC may not be prevented from being formed on the first electrode AE1, and the first light emitting pattern EM1 and the second electrode CE1 disposed on the first electrode AE1 may be prevented from being damaged by the under-cut part UC. The second electrode CE1 may be prevented from being disconnected by the under-cut part UC. According to the disclosure, the display panel DP may be improved in reliability.

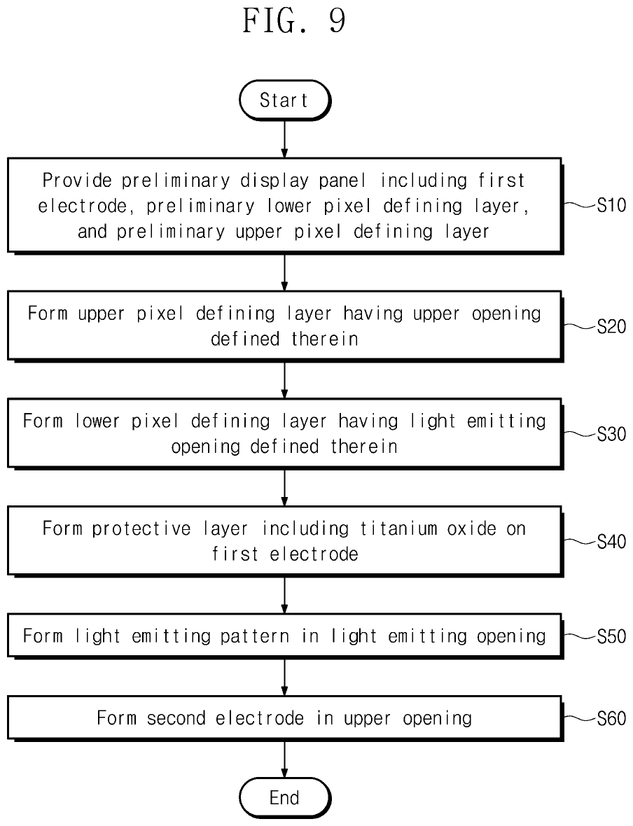

FIG. 9 is a schematic flowchart illustrating a method for manufacturing a display panel, according to an embodiment of the disclosure.

Referring to FIG. 9, the method for manufacturing the display panel according to an embodiment may include providing a preliminary display panel (S10), forming an upper pixel defining layer (S20), forming a lower pixel defining layer (S30), forming a protective layer (S40), forming a light emitting pattern (S50), and forming a second electrode (S60).

The preliminary display panel provided in the providing of the preliminary display panel (S10), may include a base layer, a first electrode disposed on the base layer, a preliminary lower pixel defining layer covering the first electrode, and a preliminary upper pixel defining layer covering the preliminary lower pixel defining layer.

In the forming of the upper pixel defining layer (S20), the upper pixel defining layer may be formed by etching a portion, which may overlap the first electrode, of the preliminary upper pixel defining layer. A portion having no preliminary upper pixel defining layer may be defined as an upper opening. In other words, the upper pixel defining layer having the upper opening defined therein may be formed from the preliminary upper pixel defining layer.

In the forming of the lower pixel defining layer (S30), the lower pixel defining layer may be formed by etching a portion, which may overlap the first electrode and the upper opening, of the preliminary lower pixel defining layer. A portion having no preliminary lower pixel defining layer may be defined as a light emitting opening. In other words, the lower pixel defining layer having the light emitting opening defined therein may be formed from the preliminary lower pixel defining layer. The upper opening and the light emitting opening may overlap each other to expose a top surface of a portion of the first electrode.

The protective layer in the forming of the protective layer (S40) may be formed by depositing a deposition material on the first electrode having an exposed top surface. The protective layer formed in the forming of the protective layer (S40) may include a titanium oxide. The protective layer may protect the first electrode and improve the reliability of the first electrode. The protective layer may be formed through the deposition process. To form the protective layer, the patterning of the deposition layer may be omitted. Accordingly, the protective layer may be formed through a simplified process.

In the forming of the light emitting pattern (S50), the light emitting pattern may be formed by depositing a light emitting material on the protective layer. In the forming of the second electrode (S60), the second electrode may be formed by depositing a conductive material on the light emitting pattern. The first electrode, the protective layer, the light emitting pattern, and the second electrode formed to correspond to the upper opening and the light emitting opening may correspond to the light emitting element.

Hereinafter, steps of the method for manufacturing the display panel according to an embodiment will be described in detail with reference to accompanying drawings.

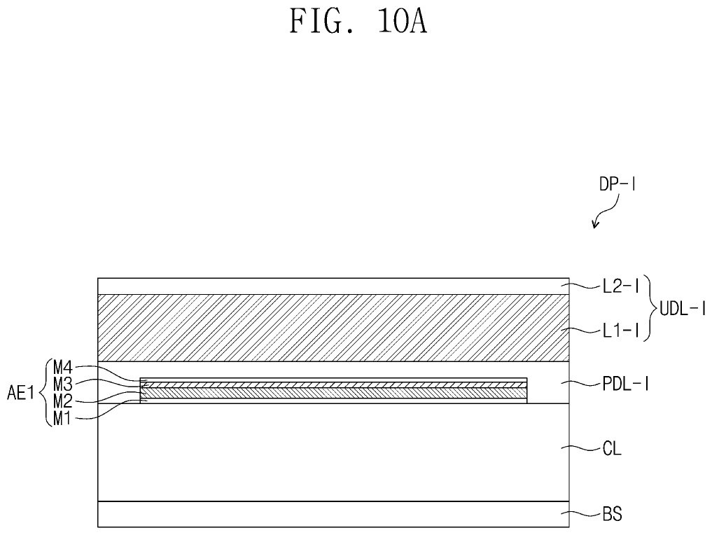

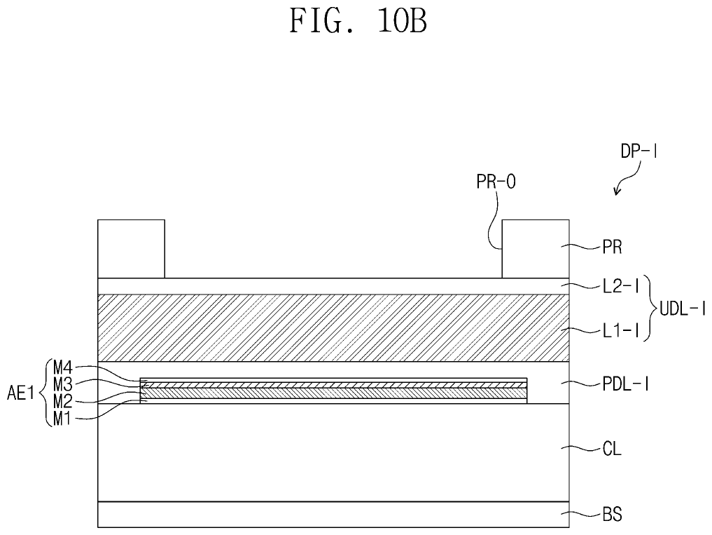

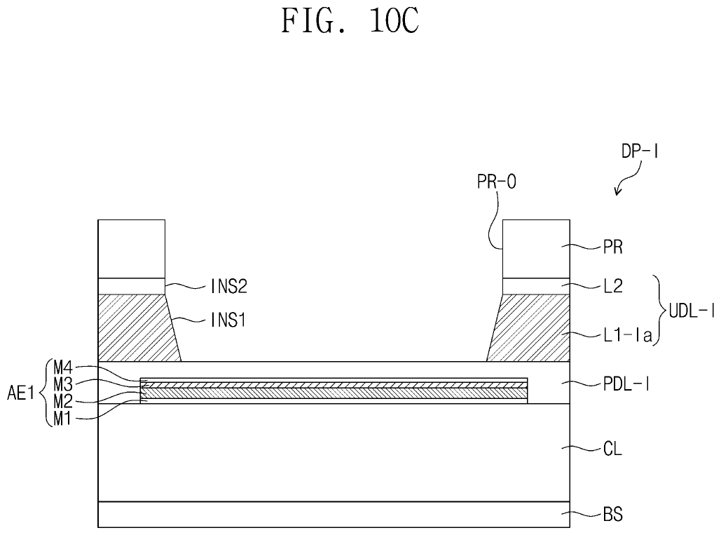

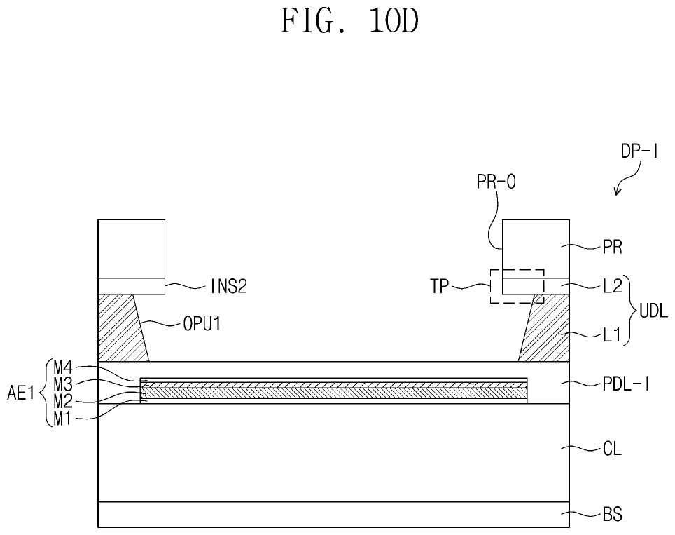

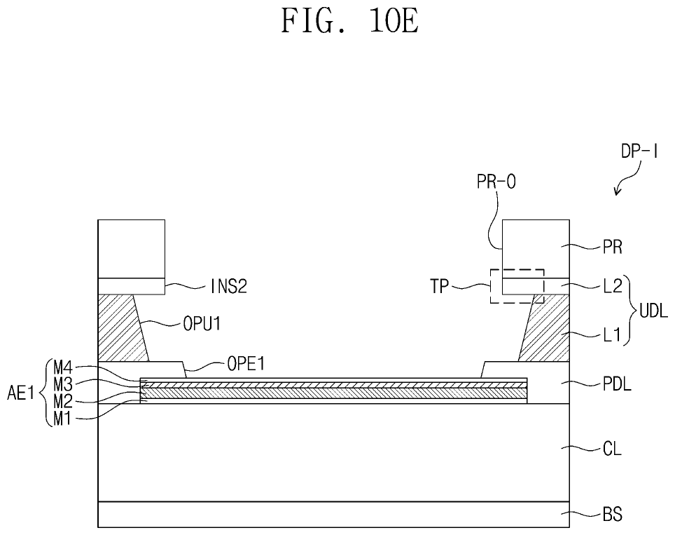

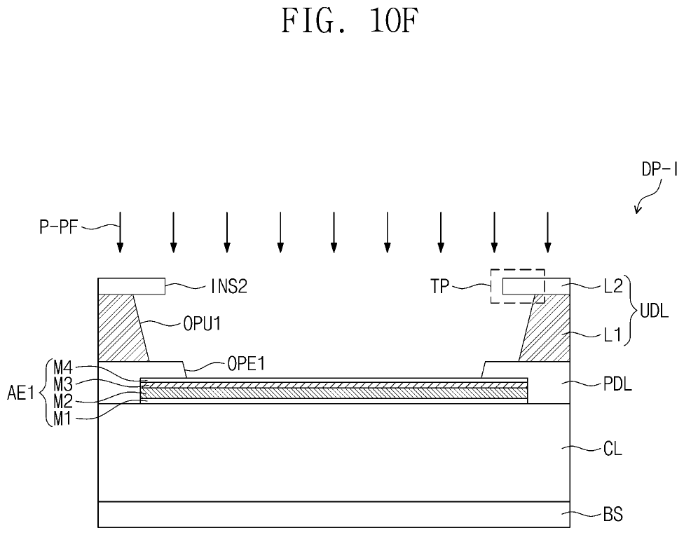

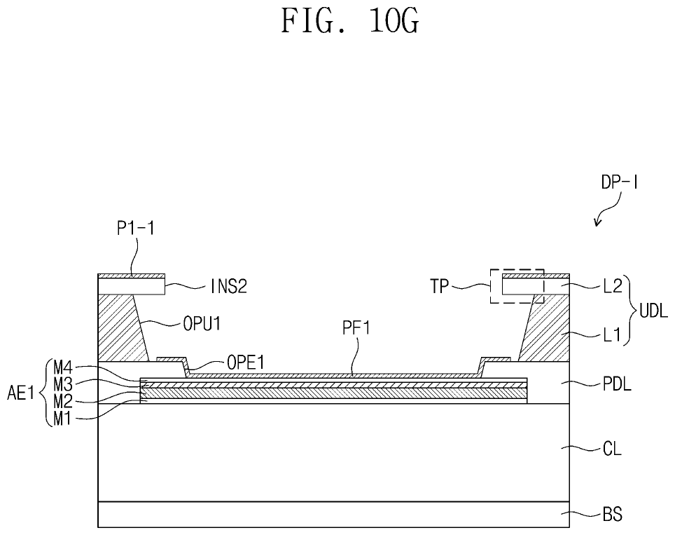

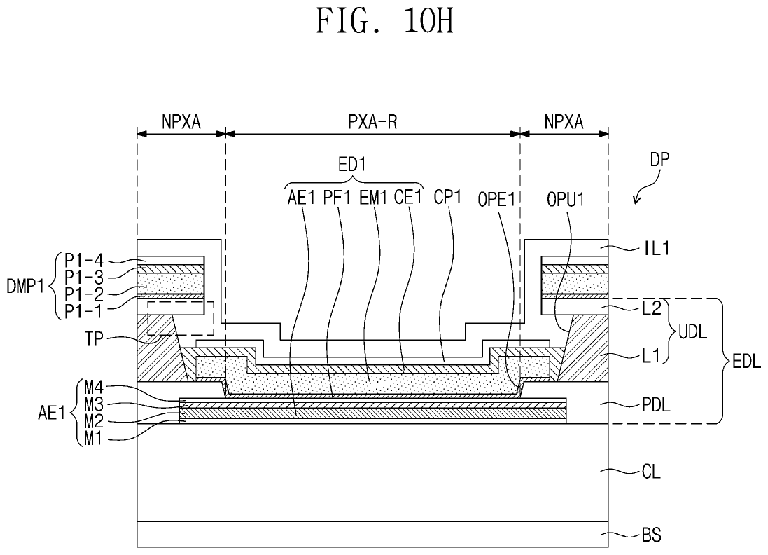

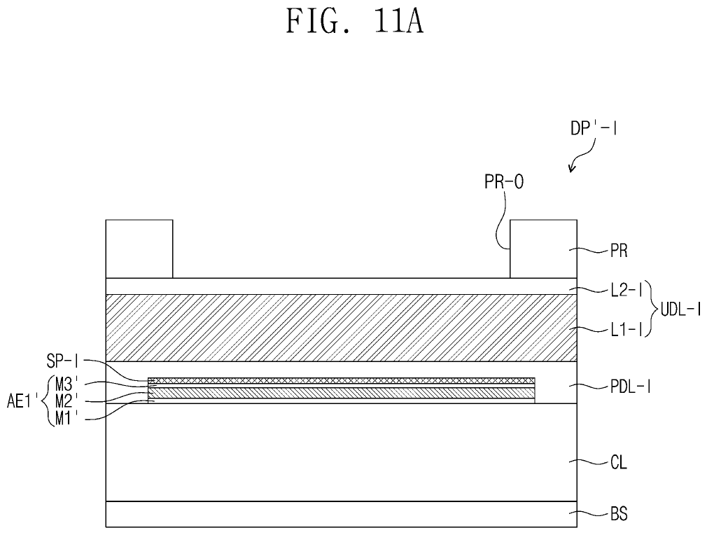

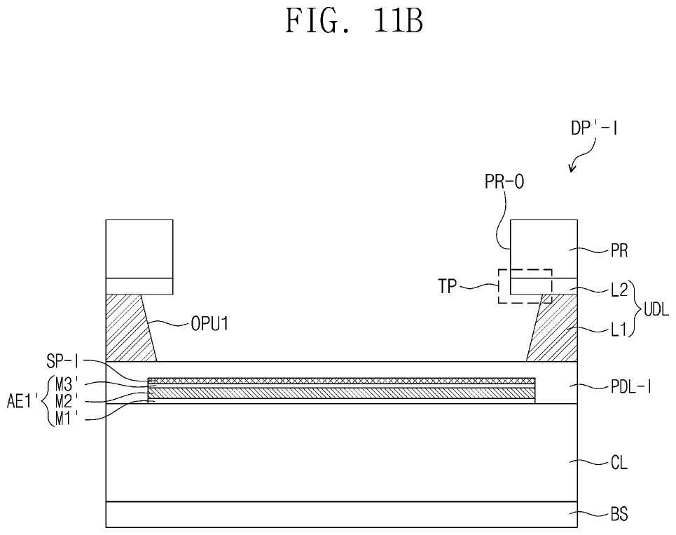

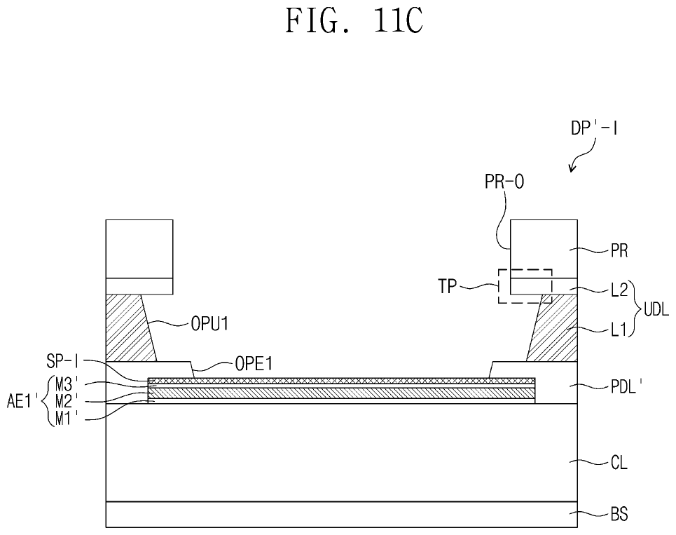

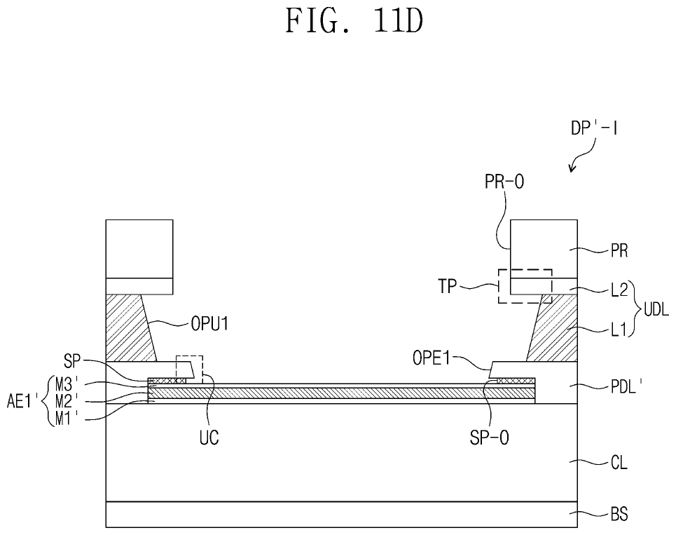

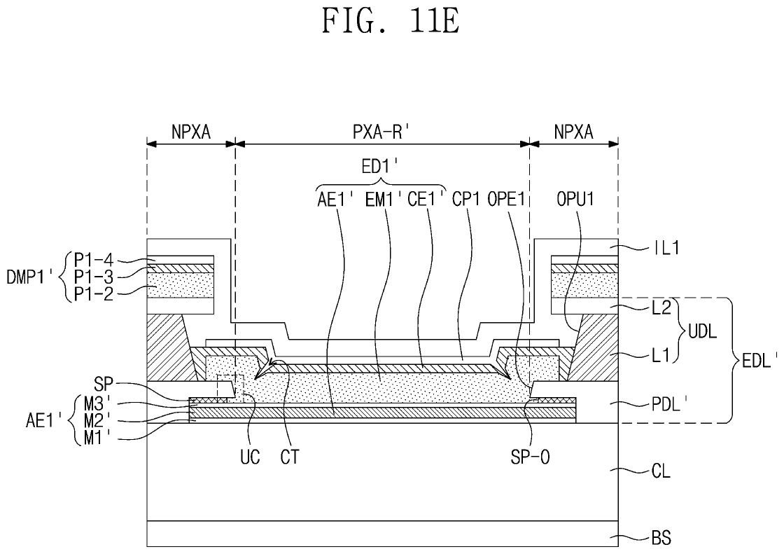

FIGS. 10A to 10H are cross-sectional views illustrating the steps of the method for manufacturing the display panel according to an embodiment of the disclosure. FIGS. 11A to 11E are cross-sectional views illustrating steps of the method for manufacturing the display panel, according to a comparative example of the disclosure.

FIGS. 10A to 10H are schematic views sequentially illustrating operations of the method for manufacturing the display panel DP according to an embodiment of FIG. 7A. FIGS. 11A to 11E are schematic views sequentially illustrating operations of the method for manufacturing the display panel DP according to a comparative example of FIG. 7B. The following description will be made while comparing one step of the method for manufacturing the display panel according to an embodiment of the disclosure with one step of the method for manufacturing the display panel according to a comparative example.

Referring to FIG. 10A, the method for manufacturing the display panel according to an embodiment may include providing a preliminary display panel DP-I (S10) (see FIG. 9). The preliminary display panel DP-I may include the base layer BS, the circuit layer CL, the first electrode AE1, a preliminary lower pixel defining layer PDL-I, and a preliminary upper pixel defining layer UDL-I.

The first electrode AE1 may include the first to fourth conductive layers M1, M2, M3, and M4, and the description described above may be applied to each layer.

The preliminary lower pixel defining layer PDL-I may cover the first electrode AE1 and may be disposed on the circuit layer CL. The preliminary lower pixel defining layer PDL-I may be formed on the first electrode AE1 through a deposition process.

A first preliminary upper layer L1-I may be disposed on the preliminary lower pixel defining layer PDL-I. A second preliminary upper layer L2-I may be disposed on the first preliminary upper layer L1-I. Each of the first preliminary upper layer L1-I and the second preliminary upper layer L2-I may be formed through the deposition process. The first preliminary upper layer L1-I and the second preliminary upper layer L2-I sequentially stacked on each other may correspond to the preliminary upper pixel defining layer UDL-I.

The first preliminary upper layer L1-I and the second preliminary upper layer L2-I may include mutually different conductive materials. The first preliminary upper layer L1-I may be disposed to have a thickness thicker than the thickness of the second preliminary upper layer L2-I.

Referring to FIG. 10B, in the forming of the upper pixel defining layer UDL (see FIG. 10D) (S20; see FIG. 9), a photoresist layer PR may be formed on the preliminary upper pixel defining layer UDL-I. The photoresist layer PR may be formed by applying a photosensitive material on the preliminary upper pixel defining layer UDL-I, forming a preliminary photoresist layer, and patterning the photoresist layer by using a mask. A photo opening PR-O may be formed through the photoresist layer PR.

The photo opening PR-O may overlap the first electrode AE1 when viewed in a plan view. A portion of the top surface of the second preliminary upper layer L2-I may be exposed through the photo opening PR-O. The region in which the photo opening PR-O is formed may correspond to a region for etching the preliminary upper pixel defining layer UDL-I through the etching process.

Referring to FIG. 11A, a preliminary display panel DP′-I according to a comparative example may include the circuit layer CL, the first electrode AE1′, an initial sacrificial pattern SP-I, the preliminary lower pixel defining layer PDL-I, and the preliminary upper pixel defining layer UDL-I.

The first electrode AE1′ may include the first to third conductive layers M1′, M2′, and M3′, and the description described above may be applied to each layer. The preliminary display panel DP′-I according to a comparative example may further include an initial sacrificial pattern SP-I, which may be different from the preliminary display panel DP-I (see FIG. 10B) according to the disclosure. The initial sacrificial pattern SP-I may be disposed on the first electrode AE1′. The initial sacrificial pattern SP-I may be patterned and formed simultaneously with a patterning process for forming the conductive layers M1′, M2′, and M3′ of the first electrode AE1′.

The lower pixel defining layer PDL may be disposed on the circuit layer CL to cover the first electrode AE1′ and the initial sacrificial pattern SP-I′. The first preliminary upper layer L1-I and the second preliminary upper layer L2-I of the preliminary upper pixel defining layer UDL-I may be sequentially stacked on each other on the lower pixel defining layer PDL.

After forming the second preliminary upper layer L2-I, the photoresist layer PR having the photo opening PR-O defined therein may be formed by applying a photoresistive material on the preliminary upper pixel defining layer UDL-I and by performing a patterning process. The photo opening PR-O may overlap the first electrode AE1′ when viewed in a plan view. A portion of the top surface of the second preliminary upper layer L2-I may be exposed through the photo opening PR-O.

Referring to FIGS. 10C and 10D, in the forming of the upper pixel defining layer UDL (S20; see FIG. 9), the upper pixel defining layer UDL may be formed by patterning the preliminary upper pixel defining layer UDL-I.

Referring to FIG. 10C, the first etching process for the first preliminary upper layer L1-I (see FIG. 10B) and the second preliminary upper layer L2-I (see FIG. 10B) may be performed using the photoresist layer PR having the photo opening PR-O defined therein, as a mask. A (1-1)-th preliminary upper layer L1-Ia and the second upper layer L2 may be formed by removing a region, which may overlap the photo opening PR-O, of the first preliminary upper layer L1-I (see FIG. 10B) and the second preliminary upper layer L2-I (see FIG. 10B).

The first etching process may be dry etching. The first etching process of the first preliminary upper layer L1-I (see FIG. 10B) and the second preliminary upper layer L2-I (see FIG. 10B) may be performed under an etching environment in which the first preliminary upper layer L1-I (see FIG. 10B) and the second preliminary upper layer L2-I (see FIG. 10B) have a substantially equal etching selectivity. Accordingly, an inner side surface INS1 of the (1-1)-th preliminary upper layer L1-Ia and an inner side surface INS2 of the second upper layer L2 which are exposed through the etching process may be substantially aligned.

Thereafter, a second etching process may be performed to additionally etch the (1-1)-th preliminary upper layer L1-Ia. The second etching process may be performed by using the photoresist layer PR as a mask. The second etching process may be a wet etching process. The second etching process may be performed under an environment in which the etching selectivity is made between the (1-1)-th preliminary upper layer L1-Ia and the second upper layer L2. The first upper layer L1 may be formed by additionally etching the (1-1)-th preliminary upper layer L1-Ia. The first upper opening OPU1 may be defined by the inner side surface of the first upper layer L1.

The inner side surface of the first upper layer L1 may be further recessed than the inner side surface of the (1-1)-th preliminary upper layer L1-Ia, when viewed from the inner side surface INS2 of the second upper layer L2. In other words, the inner side surface INS2 of the second upper layer L2 may further protrude toward the center of the first electrode AE1 rather than the inner side surface of the first upper layer L1. In the second etching process, as the etching rate of the (1-1)-th preliminary upper layer L1-Ia is greater than the etching rate of the second upper layer L2 with respect to the etching solution, an additional etching process may be performed with respect to the (1-1)-th preliminary upper layer L1-Ia. As the inner side surface INS2 of the second upper layer L2 disposed on the first upper layer L1 protrudes more than the inner side surface of the first upper layer L1, the tip part TP may be formed on the upper pixel defining layer UDL.

The first upper layer L1 and the second upper layer L2 formed from the preliminary upper pixel defining layer UDL-I through the first and second etching processes may correspond to the upper pixel defining layer UDL. In other words, the upper pixel defining layer UDL having the first upper opening OPU1 and the tip part TP may be formed from the preliminary upper pixel defining layer UDL-I through the first and second etching processes. The first upper opening OPU1 may overlap the first electrode AE1 when viewed in a plan view, and a portion of the top surface of the preliminary lower pixel defining layer PDL-I may be exposed.

Referring to FIG. 11B, the upper pixel defining layer UDL may be formed through an etching process of the preliminary upper pixel defining layer UDL-I (see FIG. 11A) using the photoresist layer PR as a mask. The etching process of the preliminary upper pixel defining layer UDL-I (see FIG. 11A) may be the same as the first and second etching processes described above with reference to FIGS. 10C and 10D. The upper opening OPU1 and the tip part TP that overlap the first electrode AE1′ may be formed in the upper pixel defining layer UDL. The upper opening OPU1 may expose a portion of the top surface of the preliminary lower pixel defining layer PDL-I.

Referring to FIG. 10E, in the forming of the lower pixel defining layer PDL (S30) (see FIG. 9), the lower pixel defining layer PDL may be formed through patterning of the preliminary lower pixel defining layer PDL-I (see FIG. 10D).

The etching process (hereinafter, referred to as the third etching process) of the preliminary lower pixel defining layer PDL-I (see FIG. 10D) may be performed by using the photoresist layer PR having the photo opening PR-O defined therein and the upper pixel defining layer UDL having the first upper opening OPU1 defined therein, as a mask. The third etching process may be a dry etching process.

The lower pixel defining layer PDL may be formed by removing a region, which may overlap the photo opening PR-O and the first upper opening OPU1, of the preliminary lower pixel defining layer PDL-I (see FIG. 10D). The first light emitting opening OPE1 may be defined by the inner side surface of the lower pixel defining layer PDL. The first light emitting opening OPE1 may overlap the first electrode AE1, when viewed in a plan view. The first light emitting opening OPE1 may expose a portion of the top surface of the fourth conductive layer M4 which is the uppermost layer of the first electrode AE1. In the third etching process for forming the first light emitting opening OPE1, a portion of the top surface of the fourth conductive layer M4 may be etched together. Even in case that the fourth conductive layer M4 is etched, the third conductive layer M3 disposed at a lower portion of the fourth conductive layer M4 may serve as an etching stopper. Accordingly, the second conductive layer M2 serving as a main layer of the first electrode AE1 may be prevented from being damaged. Accordingly, the third conductive layer M3 and the fourth conductive layer M4 disposed on the second conductive layer M2 may perform a hard mask function.

Referring to FIGS. 10F and 10G, after the first to third etching processes for forming the upper pixel defining layer UDL and the lower pixel defining layer PDL, the photoresist layer PR (see FIG. 10E) may be removed. In the forming of the protective layer PF1 (S40; see FIG. 9), after removing the photoresist layer PR (see FIG. 10E), a protective layer composition P-PF may be deposited on the first electrode AE1. According to an embodiment, the protective layer composition P-PF may include titanium.

The first protective layer PF1 may be formed by depositing the protective layer composition P-PF on the first electrode AE1. The protective layer composition P-PF may be deposited such that the first protective layer PF1 has a thinner thickness. For example, the thickness of the first protective layer PF1 may be about 30 Å to about 50 Å. As the first protective layer PF1 has a thinner thickness, a deposition process of the first protective layer PF1 may be easily performed, and the first protective layer PF1 including titanium oxide TiOx may be formed without separate heat treatment. However, the disclosure is not limited thereto. For example, after depositing the protective layer composition P-PF, the first protective layer PF1 including titanium oxide (TiOx) may be formed through additional heat treatment at about 200° C.

The first protective layer PF1 formed on the fourth conductive layer M4 of the first electrode AE1 may be formed separately from the (1-1)-th pattern part P1-1 formed on the upper pixel defining layer UDL due to the tip part TP formed on the upper pixel defining layer UDL. The first protective layer PF1 and the (1-1)-th pattern part P1-1 may be simultaneously formed in the same process and may include the same material.

As the first protective layer PF1 including titanium oxide TiOx is formed, the function of the fourth conductive layer M4 may be supplemented, even if a portion of the fourth conductive layer M4 of the first electrode AE1 having a top surface exposed in the third etching process is etched. A work function of the first protective layer PF1 may be about 5.8 eV, and the first protective layer PF1 may have the same hole injection characteristics as that of the fourth conductive layer M4 including indium tin oxide ITO. According to an embodiment, although the arrangement of the initial sacrificial pattern SP-I (see FIG. 11C) is omitted, the first protective layer PF1 may prevent the driving characteristic of the first electrode AE1 from being degraded, even after etching processes.

Since the first protective layer PF1 including titanium oxide TiOx prevents the driving characteristics of the first electrode AE1 from being degraded, the patterning process may be omitted, which may be different from the initial sacrificial pattern SP-I (see FIG. 11C) according to a comparative example. Accordingly, the manufacturing process of the display panel may be simplified.

Referring to FIG. 10H, the first light emitting pattern EM1, the second electrode CE1, the first capping pattern CP1, and the first inorganic layer IL1 may be sequentially deposited on the first protective layer PF1. The first light emitting pattern EM1 may be formed in the region of the first light emitting opening OPEL by the upper pixel defining layer UDL having the tip part TP, without using the fine metal mask. Accordingly, it is possible to prevent process problems such as residual foreign matter and imprinting occurring in the patterning process using a fine metal mask. As the first light emitting pattern EM1 having a fine size may be formed, the display panel DP for implementing a higher resolution may be manufactured. In the process of forming the first light emitting pattern EM1, the (1-2)-th pattern part P1-2 separated from the first light emitting pattern EM1 by the upper pixel defining layer UDL and including the same material as the first light emitting pattern EM1 may be formed.

The second electrode CE1 may be deposited in the first upper opening OPU1 of the upper pixel defining layer UDL. The second electrode CE1 may be formed to be separated from the (1-3)-th pattern part P1-3 by the upper pixel defining layer UDL having the tip part TP. The second electrode CE1 may contact the upper pixel defining layer UDL having conductivity in the first upper opening OPU1.

The first capping pattern CP1 may be deposited in the first upper opening OPU1 of the upper pixel defining layer UDL. The first capping pattern CP1 may be formed to be separated from the (1-4)-th pattern part P1-4 by the upper pixel defining layer UDL having the tip part TP.

The first inorganic layer IL1 may cover the first light emitting element ED1 and the first dummy pattern DMP1. A portion of the first inorganic layer IL1 may be disposed inside the first upper opening OPU1. The first inorganic layer IL1 may cover the first dummy pattern DMP1 while making contact with the inner side surface of the first upper layer L1 and the inner side surface INS2 (see FIG. 10G) of the second upper layer L2. The first inorganic layer IL1 may prevent moisture and/or oxygen from being introduced into the first light emitting element ED1.

Referring to FIG. 11C, through an etching process, the preliminary lower pixel defining layer PDL-I (see FIG. 11B) may be patterned to form the lower pixel defining layer PDL′ having the light emitting opening OPE1 defined therein. The etching process may be a dry etching process.

According to a comparative example, the light emitting opening OPEL may overlap the upper opening OPU1 and the first electrode AE1′, when viewed in a plan view, and may expose a portion of the top surface of the initial sacrificial pattern SP-I. The initial sacrificial pattern SP-I may be disposed on the first electrode AE1′ to prevent damage to the first electrode AE1′ during an etching process. The initial sacrificial pattern SP-I may include indium gallium zinc oxide (IGZO) or indium zinc oxide (IZO) to protect the first electrode AE1′ from etching.

Referring to FIG. 11D, the method for manufacturing the display panel according to a comparative example may include patterning the initial sacrificial pattern SP-I (see FIG. 11C). The initial sacrificial pattern SP-I (see FIG. 11C) in which the protection function of the first electrode AE1′ is completed may be patterned to form the opening SP-O overlapping the first electrode AE1′. In other words, the sacrificial pattern SP having the opening SP-O defined therein may be formed by patterning the initial sacrificial pattern SP-I (see FIG. 11C). In case that the initial sacrificial pattern SP-I (see FIG. 11C) is not patterned in the region corresponding to the first light emitting opening OPE1, the initial sacrificial pattern SP-I may interfere with the injection of holes, thereby reducing the driving efficiency of the first electrode AE1′.

The initial sacrificial pattern SP-I (see FIG. 11C) may be patterned through wet etching. In the etching process of the initial sacrificial pattern SP-I (see FIG. 11C), the photoresist layer PR and the upper pixel defining layer UDL may function as masks. The inner side surface of the sacrificial pattern SP defining the opening SP-O may be more recessed outward than the inner side surface of the lower pixel defining layer PDL′ defining the light emitting opening OPE1. In other words, the inner side surface of the lower pixel defining layer PDL′ may protrude more toward the center of the first electrode AE1′ than the inner side surface of the sacrificial pattern SP. Accordingly, the under-cut part UC may be formed on the first electrode AE1′ of the comparative example.

Referring to FIG. 11E, after forming the sacrificial pattern SP having the opening SP-O, the light emitting pattern EM1′, a second electrode CE1′, the capping pattern CP1, and the first inorganic layer IL1 may be sequentially deposited on the first electrode AE1′. In the comparative example, the light emitting pattern EM1′ deposited on the under-cut part UC may be partially recessed, stepped, or damaged by the under-cut part UC. The second electrode CE1′ formed on the light emitting pattern EM1′ may be damaged or disconnected (see reference sign CT) corresponding to the under-cut part UC. Accordingly, according to a comparative example of protecting the first electrode AE1′ using the sacrificial pattern SP, the under-cut part UC may be formed on the first electrode AE1′. Accordingly, the light emitting element ED1′ of the display panel DP′ may be damaged to reduce the reliability of the display panel DP′.

However, as illustrated in FIGS. 10E to 10H, according to an embodiment, the third conductive layer M3 including a zinc-based oxide is included in the first electrode AE1. Accordingly, the first electrode AE1 may be prevented from being damaged in etching processes for forming the upper pixel defining layer UDL and the lower pixel defining layer PDL. The additional initial sacrificial pattern SP-I (see FIG. 11A) may be omitted. The fourth conductive layer M4 including indium tin oxide may be included in the first electrode AE1, thereby preventing the driving voltage of the first electrode AE from being shifted.

According to an embodiment, the initial sacrificial pattern SP-I (see, e.g., FIG. 11A) may be omitted, thereby enabling skipping of a step of patterning an initial sacrificial pattern SP-I (see FIG. 11C). An under-cut part UC (see FIG. 11E) may be prevented from being formed, as the initial sacrificial pattern SP-I is patterned. Accordingly, the light emitting pattern EM1 and the second electrode CE1 may be prevented from being damaged by the under-cut part UC (see FIG. 11E), and the reliability of the display panel DP may be improved.

According to an embodiment, a protective layer PF1 is deposited on a first electrode AE1 after performing an etching process for forming the upper pixel defining layer UDL and the lower pixel defining layer PDL. Accordingly, the function of the fourth conductive layer M4 may be supplemented, and the driving reliability of the first electrode AE1 may be improved.

According to an embodiment, in the display panel, as the light emitting pattern is formed without the metal mask, the light emitting element realizing the higher resolution may be manufactured with the improved process reliability.

According to an embodiment, the light emitting element may include the protective layer interposed between the first electrode and the light emitting pattern, and the protective layer may prevent the first electrode, the light emitting pattern, and the second electrode from being damaged in the manufacturing process, without damaging the driving characteristic of the first electrode.

According to an embodiment, in the light emitting element, the layer including a titanium oxide is deposited before the light emitting pattern is formed on the first electrode, thereby preventing the under-cut part from being formed between the first electrode and the light emitting pattern, and the gas leakage and the disconnection of the second electrode caused by the under-cut part may be prevented.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display panel, comprising:
a base layer;
a lower pixel defining layer disposed on the base layer and having a first light emitting opening and a second light emitting opening which are defined in the lower pixel defining layer;
an upper pixel defining layer disposed on the lower pixel defining layer and having a first upper opening and a second upper opening which are defined in the upper pixel defining layer, and which overlap the first light emitting opening and the second light emitting opening, respectively;
a first light emitting element including a first electrode, a first protective layer, a first light emitting pattern, and a second electrode and disposed in the first upper opening; and
a second light emitting element including a first electrode, a second protective layer, a second light emitting pattern, and a second electrode and disposed in the second upper opening,
wherein each of the first protective layer and the second protective layer includes a titanium oxide.

2. The display panel of claim 1, wherein
the first protective layer overlaps the first light emitting opening, and
the second protective layer overlaps the second light emitting opening.

3. The display panel of claim 1, wherein
the first protective layer contacts the first electrode of the first light emitting element, and
the second protective layer contacts the first electrode of the second light emitting element.

4. The display panel of claim 1, wherein each of the first protective layer and the second protective layer has a thickness in a range of about 30 Å to about 50 Å.

5. The display panel of claim 1, wherein
the first protective layer overlaps an inner side surface of the lower pixel defining layer defining the first light emitting opening, and
the second protective layer overlaps an inner side surface of the lower pixel defining layer defining the second light emitting opening.

6. The display panel of claim 1, wherein
each of the first electrode of the first light emitting element and the first electrode of the second light emitting element includes first to fourth conductive layers, and
at least two conductive layers of the first to fourth conductive layers include mutually different materials.

7. The display panel of claim 6, wherein the first conductive layer and the fourth conductive layer include a same material.

8. The display panel of claim 7, wherein the second conductive layer includes silver (Ag), magnesium (Mg), aluminum (Al), platinum (Pt), palladium (Pd), gold (Au), nickel (Ni), neodymium (Nd), iridium (Ir), chromium (Cr), or a combination thereof.

9. The display panel of claim 7, wherein the third conductive layer includes at least one of indium gallium zinc oxide (IGZO), indium zinc oxide (IZO), and indium zinc tin oxide (IZTO).

10. The display panel of claim 9, wherein the fourth conductive layer includes indium tin oxide (ITO).

11. The display panel of claim 6, wherein the third conductive layer has a thickness less than a thickness of the fourth conductive layer.

12. The display panel of claim 11, wherein the third conductive layer has a thickness in a range of about 200 Å to about 300 Å.

13. The display panel of claim 11, wherein the fourth conductive layer has a thickness in a range of about 50 Å to about 100 Å.

14. The display panel of claim 1, wherein the upper pixel defining layer surrounds the second electrode of the first light emitting element and the second electrode of the second light emitting element, when viewed in a plan view.

15. The display panel of claim 1, wherein
the upper pixel defining layer includes:
a first upper layer disposed on the lower pixel defining layer and including a conductive material, and
a second upper layer disposed on the first upper layer, and
each of the second electrode of the first light emitting element and the second electrode of the second light emitting element contacts inner surfaces of the first upper layer.

16. The display panel of claim 15, wherein the second upper layer includes a conductive material different from a material of the first upper layer.

17. The display panel of claim 15, wherein
the first upper layer includes an inner side surface defining the first upper opening,
the second upper layer includes an inner side surface overlapping the first upper opening, and
the inner side surface of the second upper layer protrudes more than the inner side surface of the first upper layer toward center of the first upper opening.

18. The display panel of claim 1, wherein the first light emitting element and the second light emitting element emit mutually different color lights.

19. A display panel, comprising:
a base layer including:
a light emitting region; and
a non-light emitting region;
a lower pixel defining layer disposed in the non-light emitting region and including an insulating material;
an upper pixel defining layer disposed on the lower pixel defining layer and including a conductive material; and
a light emitting element disposed in the light emitting region, wherein
the light emitting element includes:
a first electrode disposed on the base layer;
a protective layer disposed on the first electrode and including a titanium oxide;
a light emitting pattern disposed on the protective layer; and
a second electrode disposed on the light emitting pattern, and
the protective layer overlaps a top surface of the first electrode corresponding to the light emitting region.

20. A method for manufacturing a display panel, the method comprising:
providing a preliminary display panel including a base layer, a first electrode disposed on the base layer, a preliminary lower pixel defining layer overlapping the first electrode, and a preliminary upper pixel defining layer overlapping the preliminary lower pixel defining layer;
forming an upper pixel defining layer having an upper opening defined in the upper pixel defining layer by patterning the preliminary upper pixel defining layer;
forming a lower pixel defining layer having a light emitting opening overlapping the upper opening by patterning the preliminary lower pixel defining layer;
forming a protective layer including titanium oxide on the first electrode exposed through the light emitting opening;
forming a light emitting pattern on the protective layer; and
forming a second electrode contacting the upper pixel defining layer, in the upper opening.
